(19) United States
(12) Patent Application Publication
(10) Pub. No.: US 2026/0107390 A1
(43) Pub. Date: Apr. 16, 2026

(54) ELECTRONIC DEVICE INCLUDING CAPACITOR ARRAY FOR CONNECTION OF DISPLAY DRIVER IC

(71) Applicant: Samsung Electronics Co., Ltd., Suwon-si (KR)

(72) Inventors: Seunghyup HAN, Suwon-si (KR); Youngjoon KIM, Suwon-si (KR); Hyunsuk JUNG, Suwon-si (KR); Hun HEO, Suwon-si (KR)

(21) Appl. No.: 19/384,806

(22) Filed: Nov. 10, 2025

Related U.S. Application Data
(63) Continuation of application No. PCT/KR2025/015863, filed on Oct. 2, 2025.

(30) Foreign Application Priority Data
Sep. 10, 2025 (KR) 10-2025-0129000
Jul. 29, 2025 (KR) 10-2025-0103091
Oct. 11, 2024 (KR) 10-2024-0138747

(51) Int. Cl. H05K 1/18; H05K 5/02

(52) U.S. Cl. CPC H05K 1/189; H05K 5/0217; H05K 2201/10015; H05K 2201/10128

(57) ABSTRACT

An electronic device may include: a housing, a printed circuit board (PCB) accommodated in the housing and having a processor disposed thereon, a substrate, a display panel disposed on the substrate, a driver circuit disposed under the display panel and electrically connected to the display panel, and a flexible printed circuit board (FPCB) electrically connected to the driver circuit. The flexible printed circuit board may include a power wire configured to deliver power supplied via the printed circuit board to the driver circuit, and an array of capacitors electrically coupled to the power wire and arranged at least partially substantially perpendicular to a longitudinal direction of the driver circuit.

### CROSS-REFERENCE TO RELATED APPLICATIONS

This application is a continuation of International Application No. PCT/KR2025/015863 designating the United States, filed on October 2, 2025, in the Korean Intellectual Property Receiving Office and claiming priority to Korean Patent Application Nos. 10-2024-0138747, filed on October 11, 2024, 10-2025-0103091, filed on July 29, 2025, and 10-2025-0129000, filed on September 10, 2025, in the Korean Intellectual Property Office, the disclosures of each of which are incorporated by reference herein in their entireties.

### BACKGROUND

### Field

The disclosure relates to an electronic device including a capacitor array structure for connection of a display driver IC.

### Description of Related Art

In recent years, electronic devices have tended to gain higher market competitiveness as their functions become diversified and their portability improves. Even when providing the same functions, slimmer, lighter, and smaller electronic devices may be preferred by users.

The operating time of an electronic device may be affected by the battery capacity of the electronic device. Accordingly, despite slimming and downsizing of electronic devices, an internal design of an electronic device capable of increasing battery capacity may be required.

The above-described information may be provided as related art for the purpose of assisting in understanding the disclosure. No assertion or determination is made as to whether any of the above might be applicable as prior art with regard to the disclosure.

To drive a display of an electronic device, the electronic device may include a source driver integrated circuit (IC). The source driver IC may be disposed on a substrate of a display panel or on a film substrate connecting the display panel. The source driver IC may be configured to control brightness of sub-pixels by adjusting a voltage of data wires present in the display panel.

The electronic device may include capacitors disposed adjacent along a longitudinal direction of the source driver IC and configured to be connected to the source driver IC so as to stably supply power to the source driver IC.

However, such an arrangement of the capacitors may interfere with other components (e.g., a battery) from being efficiently disposed in the electronic device. In addition, in order to efficiently dispose other components, when the capacitors are disposed at a relatively long distance from the source driver IC, power may not be stably supplied to the source driver IC.

### SUMMARY

According to various example embodiments of the disclosure, by arranging an array of capacitors along a direction perpendicular to a longitudinal direction of a source driver IC, an area in which other components (e.g., a battery) may be disposed may be increased.

According to various example embodiments of the disclosure, an electronic device may be configured, such that power is stably supplied to a source driver IC.

According to various example embodiments, an electronic device may include: a housing; a printed circuit board (PCB) accommodated in the housing and having a processor disposed thereon; a substrate; a display panel disposed on the substrate; a driver circuit disposed under the display panel and electrically connected to the display panel; a flexible printed circuit board electrically connected to the driver circuit, wherein the flexible printed circuit board may include a power wire configured to deliver power supplied via the printed circuit board to the driver circuit, and flexible printed circuit board may include an array of capacitors electrically coupled to the power wire and arranged at least partially substantially perpendicular to a longitudinal direction of the driver circuit.

In the electronic device according to various example embodiments of the disclosure, by arranging an array of capacitors along a direction perpendicular to a longitudinal direction of a source driver IC, an area in which other components (e.g., a battery) may be disposed may be increased.

The electronic device according to various example embodiments of the disclosure may be configured to stably supply power to the source driver IC.

Various other effects understood directly or indirectly through the disclosure may be provided.

Advantageous effects obtainable from the disclosure may not be limited to the above-mentioned effects, and other effects which are not mentioned herein may be clearly understood from the following description by those skilled in the art to which the disclosure pertains.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

With regard to the description of the drawings, the same or like reference signs may be used to designate the same or like elements.

FIG. 1A is a block diagram of an example electronic device in a network environment, according to various embodiments;

FIG. 1B is a block diagram illustrating an example configuration of a display module according to various embodiments;

FIG. 2A is a diagram illustrating a front view of a multi-foldable electronic device in an unfolded state according to various embodiments;

FIG. 2B is a diagram illustrating a rear view of the multi-foldable electronic device in the unfolded state according to various embodiments;

FIG. 2C is a diagram illustrating a side view of the multi-foldable electronic device in a state in which a first housing and a second housing are folded, and the first housing and a third housing are unfolded according to various embodiments;

FIG. 2D is a diagram illustrating a side view of the multi-foldable electronic device in a state in which the first housing, the second housing, and the third housing are folded according to various embodiments;

FIG. 3 is an exploded perspective view of a multi-foldable electronic device according to various embodiments;

FIG. 4A is a diagram illustrating a state in which a driver circuit is disposed on a substrate according to various embodiments;

FIG. 4B is a diagram illustrating a state in which a driver circuit is disposed on a film substrate according to various embodiments;

FIG. 5A is a perspective view illustrating a multi-foldable electronic device in an assembled state in which a second rear cover is removed according to various embodiments;

FIG. 5B is a partially enlarged perspective view illustrating the multi-foldable electronic device in a state in which the second housing and a second rear cover are removed according to various embodiments;

FIGS. 6A, 6B and 6C are diagrams illustrating partial plan views of an array of capacitors according to various embodiments;

FIG. 7 is a graph illustrating impedance comparison results between an embodiment of the disclosure and comparative examples.

FIG. 8A is a diagram illustrating a power wire configuration of a comparative example.

FIG. 8B is a diagram illustrating a power wire configuration according to various embodiments;

FIG. 8C is a graph illustrating impedance comparison results between the power wire configuration according to various embodiments of the disclosure and the power wire configuration of the comparative example.

FIG. 9 is a diagram illustrating a plan view of a flexible printed circuit board according to various embodiments;

FIGS. 10A and 10B are diagrams illustrating power wires according to various embodiments; and

FIG. 11 is a diagram illustrating a plurality of power wire connection structures in a driver circuit according to various embodiments.

### DETAILED DESCRIPTION

Hereinafter, various example embodiments of the disclosure will be described in greater detail with reference to the accompanying drawings. However, the disclosure may be implemented in various different forms and is not limited to the various example embodiments set forth herein. With regard to the description of the drawings, the same or like reference signs may be used to designate the same or like elements. In the drawings and the relevant descriptions, description of well-known functions and configurations may be omitted for the sake of clarity and brevity.

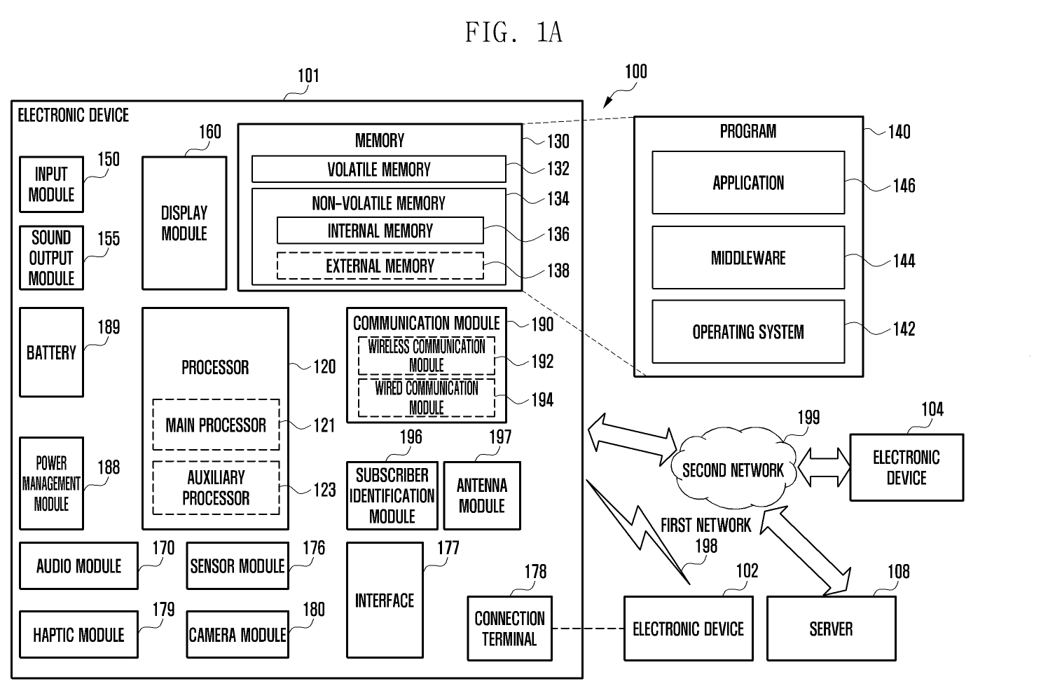

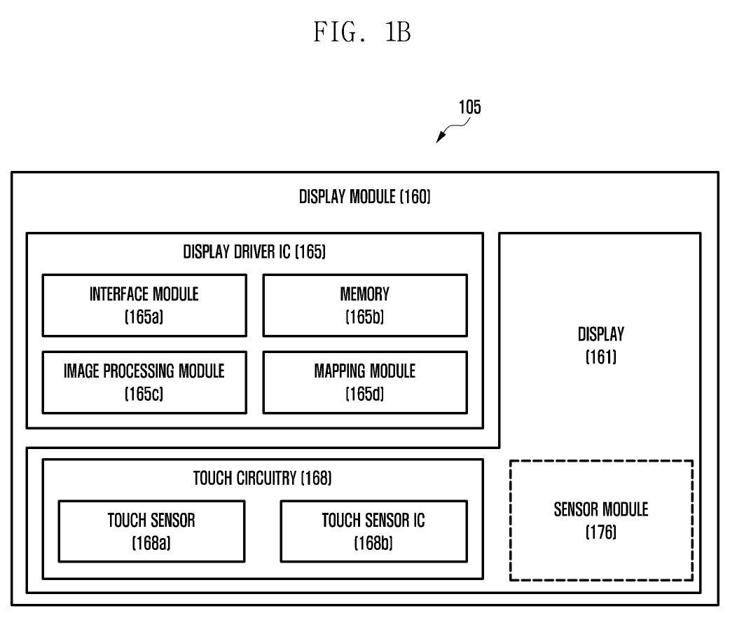

FIG. 1A is a block diagram illustrating an example electronic device in a network environment according to various embodiments.

Referring to FIG. 1a, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited /disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth^{TM}, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

FIG. 1B is a block diagram illustrating an example configuration of a display module according to various embodiments.

FIG. 1B may be a block diagram 105 illustrating various components of a display module 160.

Referring to FIG. 1B, the display module 160 may include a display 161 and a display driver IC (DDI) 165 configured to control the display 161. The display driver IC 165 may include an interface module (e.g., including circuitry) 165a, memory 165b (e.g., buffer memory), an image processing module (e.g., including various circuitry and/or executable program instructions) 165c, and/or a mapping module (e.g., including various circuitry and/or executable program instructions) 165d. The display driver IC 165 may receive, for example, image information including image control signals corresponding to image data or a command for controlling the image data, from another component of an electronic device 101 via the interface module 165a. In an embodiment, the image information may be received from a processor 120 (e.g., a main processor 121 (e.g., an application processor) or an auxiliary processor 123 (e.g., a graphics processing unit) operating independently of functions of the main processor 121). The display driver IC 165 may communicate with a touch circuit 168 or a sensor module (e.g., including at least one sensor)176 via the interface module 165a. The display driver IC 165 may store at least a part of the received image information in the memory 165b, for example, on a frame-by-frame basis. The image processing module 165c may include various circuitry and/or executable program instructions and perform pre-processing or post-processing (e.g., resolution, brightness, or size adjustment) on at least a part of the image data based at least on the characteristics of the image data or characteristics of the display 161. The mapping module 165d may include various circuitry and/or executable program instructions and generate a voltage value or a current value corresponding to the image data pre-processed or post-processed through the image processing module 165c. According to an embodiment, the generation of the voltage value or the current value may be performed based at least on, for example, the attributes of the pixels of the display 161 (e.g., the array of pixels (an RGB stripe or pentile structure) or the size of each of sub-pixels). At least some of the pixels of the display 161 are driven based at least partially on, for example, the voltage value or the current value, so that visual information (e.g., text, images, or icons) corresponding to the video data can be displayed through the display 161.

According to an embodiment, the display module 160 may further include a touch circuit 168. The touch circuit 168 may include a touch sensor 168a and a touch sensor IC 168b configured to control the same. The touch sensor IC 168b may control the touch sensor 168a to detect, for example, a touch input or a hovering input with respect to a specific position in the display 161. For example, the touch sensor IC 168b may detect a touch input or a hovering input by measuring a change in a signal (e.g., voltage, light amount, resistance, or charge amount) with respect to a specific position in the display 161. The touch sensor IC 168b may provide the processor 120 with information about the sensed touch input or hovering input (e.g., position, area, pressure, or time). According to an embodiment, at least a part of the touch circuit 168 (e.g., the touch sensor IC 168b) may be included as a part of the display driver IC 165 or the display 161 or a part of another component (e.g., an auxiliary processor 123) disposed outside the display module 160.

According to an embodiment, the display module 160 may further include at least one sensor (e.g., a fingerprint sensor, an iris sensor, a pressure sensor, or an illuminance sensor) of a sensor module 176, or a control circuit therefor. In this case, the at least one sensor or a control circuit for the same may be embedded in a portion of the display module 160 (e.g., the display 161 or the display IC 165) or a portion of the touch circuit 168. For example, when the sensor module 176 embedded in the display module 160 includes a biometric sensor (e.g., a fingerprint sensor), the biometric sensor may acquire biometric information (e.g., a fingerprint image) associated with a touch input through a portion of the display 161. For example, when the sensor module 176 embedded in the display module 160 includes a pressure sensor, the pressure sensor acquires pressure information associated with a touch input through all or a part of the area of the display 161. According to an embodiment, the touch sensor 168a or the sensor module 176 may be disposed between pixels of the pixel layer of the display 161, or above or below the pixel layer.

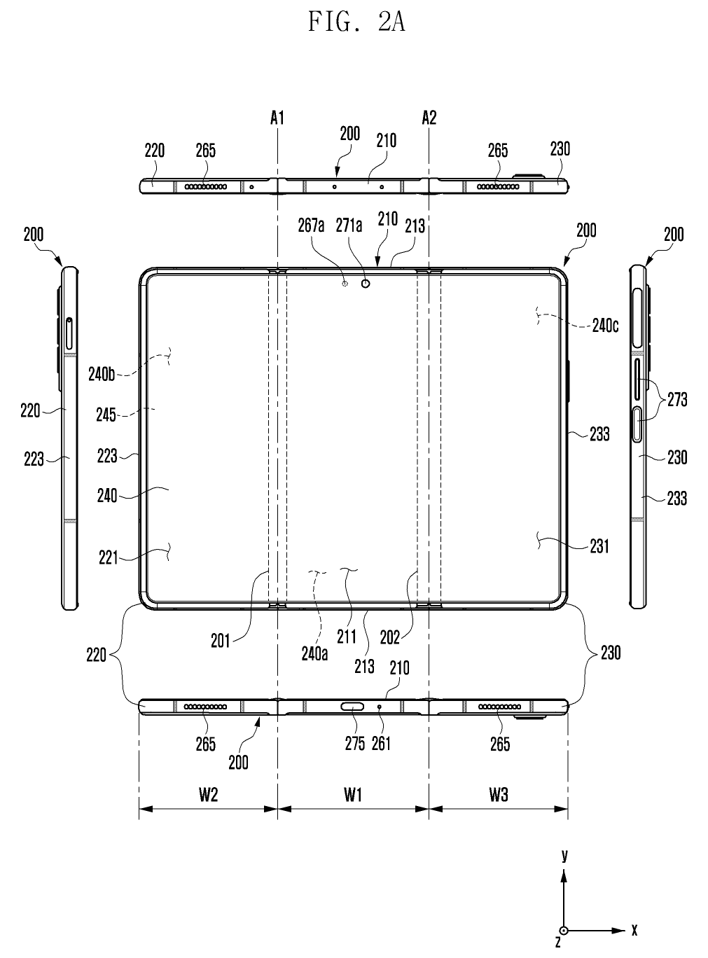

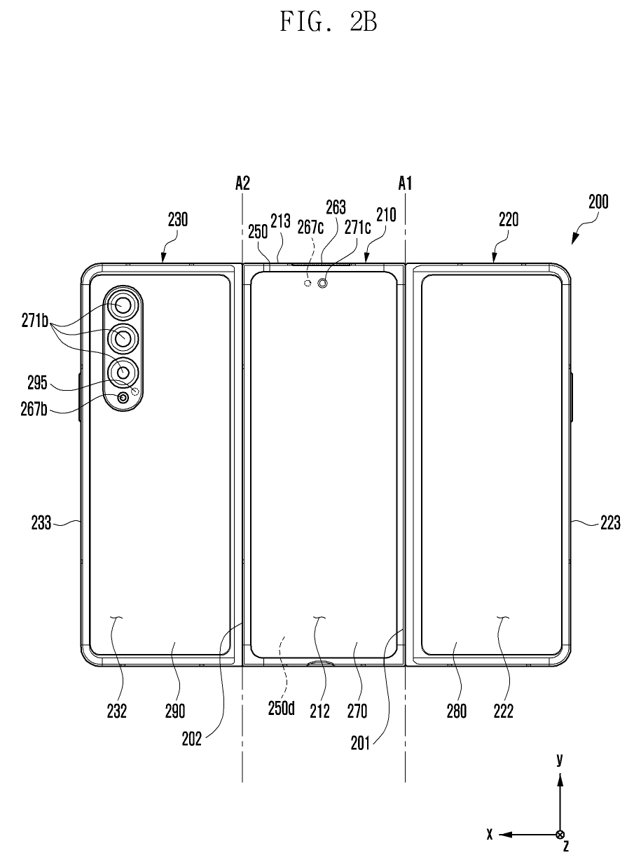

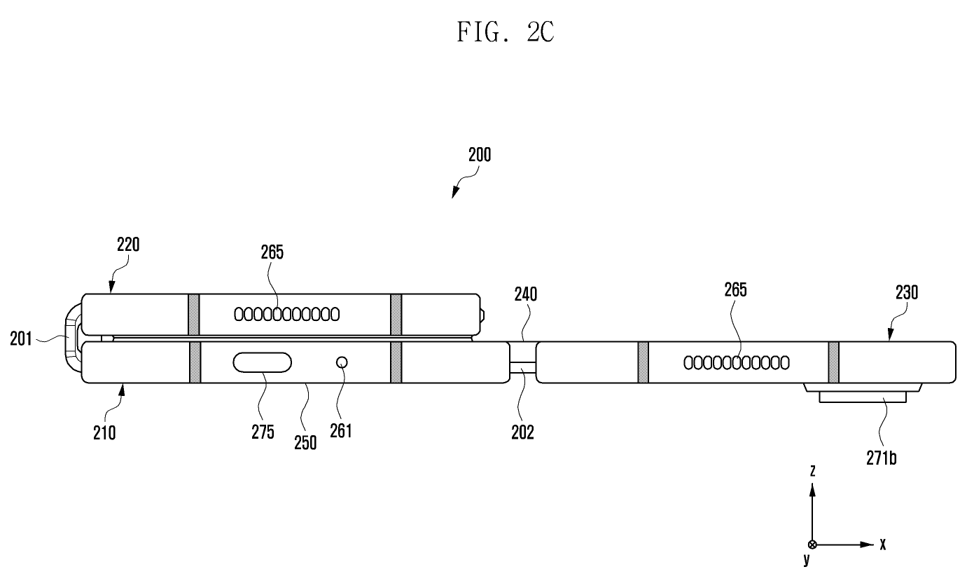

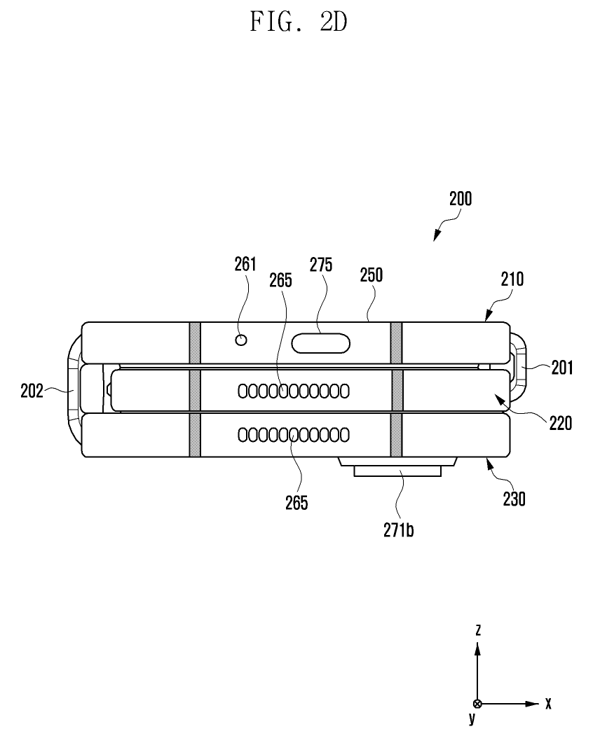

FIG. 2A is a diagram illustrating a front view illustrating a multi-foldable electronic device in an unfolded state according to various embodiments. FIG. 2B is a diagram illustrating a rear view illustrating the multi-foldable electronic device in the unfolded state according to various embodiments.

According to various embodiments, the electronic device 101 illustrated in FIG. 1A may be an example of the multi-foldable electronic device 200 disclosed below. For example, FIG. 1A illustrating the electronic device 101 may be a block diagram schematically illustrating some of the components of the multi-foldable electronic device 200 disclosed below. For example, the multi-foldable electronic device 200 disclosed below may include the processor 120, the memory 130, the input module 150, the acoustic output module 155, the display module 160, the audio module 170, the sensor module 176, the interface 177, the connector 178, the haptic module 179, the camera module 180, the antenna module 197, and/or the subscriber identification module 196 illustrated in FIG. 1a.

Referring to FIGS. 2A and 2B, the multi-foldable electronic device 200 according to an embodiment of the disclosure may include a first housing 210, a second housing 220, a third housing 230, a first hinge 201, a second hinge 202, and/or a flexible display 240.

According to an embodiment, the first housing 210 may be disposed between the second housing 220 and the third housing 230. For example, on a first side of the first housing 210 (e.g., in the -x-axis direction), the second housing 220 may be foldably and unfoldably coupled using the first hinge 201. On a second side of the first housing 210 (e.g., in the x-axis direction), the third housing 230 may be foldably and unfoldably coupled using the second hinge 202.

According to an embodiment, the second housing 220 may be disposed on the first side of the first housing 210 (e.g., in the -x-axis direction) through the first hinge 201. For example, the second housing 220 may be foldably and unfoldably coupled to the first side of the first housing 210 (e.g., in the -x-axis direction). The first hinge 201 may be at least partially coupled between the first housing 210 and the second housing 220. The first hinge 201 may be disposed so as to allow the first housing 210 and the second housing 220 to be foldable or unfoldable with respect to each other. The first hinge 201 may include a hinge assembly, a hinge device, a hinge member, a hinge plate, a hinge structure, or a hinge module. The first housing 210 and the second housing 220 may be coupled to be rotatable about a first folding axis A1 using the first hinge 201.

According to an embodiment, the third housing 230 may be disposed on the second side of the first housing 210 (e.g., the x-axis direction) via the second hinge 202. For example, the third housing 230 may be foldably and unfoldably coupled to the second side of the first housing 210 (e.g., in the x-axis direction). The second hinge 202 may be at least partially coupled between the first housing 210 and the third housing 230. The second hinge 202 may be disposed so as to allow the first housing 210 and the third housing 230 to be folded or unfolded with respect to each other. The second hinge 202 may include a hinge assembly, a hinge device, a hinge member, a hinge plate, a hinge structure, or a hinge module. The first housing 210 and the third housing 230 may be coupled to be rotatable about a second folding axis A2 using the second hinge 202.

According to an embodiment, in the multi-foldable electronic device 200, the second housing 220 may be first folded toward the first housing 210 via the first hinge 201, and the third housing 230 may be subsequently folded toward the first housing 210 via the second hinge 202. For example, the second housing 220 may be folded with respect to the first housing 210 in an in-folding manner via the first hinge 201. For example, the second housing 220 may be folded onto the first housing 210 while rotating in the z-axis direction and the x-axis direction via the first hinge 201. For example, the third housing 230 may be folded with respect to the first housing 210 in an in-folding manner via the second hinge 202. For example, the third housing 230 may be folded onto the first housing 210 while rotating in the z-axis direction and the -x-axis direction via the second hinge 202. For example, when the second housing 220 is first folded toward the first housing 210 using the first hinge 201, and the third housing 230 is subsequently folded toward the first housing 210 using the second hinge 202, the third housing 230 may be disposed on the second housing 220.

In an embodiment, a second width W2 of the second housing 220 in the horizontal direction (e.g., the -x-axis direction and the x-axis direction) may be smaller than a first width W1 of the first housing 210 in the horizontal direction (e.g., the -x-axis direction and the x-axis direction). The first width W1 of the first housing 210 in the horizontal direction (e.g., the -x-axis direction and the x-axis direction) may be substantially the same as a third width (W3) of the third housing 230 in the horizontal direction (e.g., the -x-axis direction and the x-axis direction). According to various embodiments, the third width W3 of the third housing 230 in the horizontal direction (e.g., the -x-axis direction and the x-axis direction) may be greater than or smaller than the first width W1 of the first housing 210 in the horizontal direction (e.g., the -x-axis direction and the x-axis direction). For example, the first width W1 of the first housing 210, the second width W2 of the second housing 220, and the third width W3 of the third housing 230 described above are merely examples according to an embodiment, and are not limited thereto, but may be formed to have various other widths.

According to an embodiment, the first housing 210 and the second housing 220 are disposed on both sides (e.g., in the x-axis direction and the -x-axis direction) based on the first folding axis A1 where the first hinge 201 is disposed, and may have an asymmetrical shape with respect to the first folding axis A1. According to various embodiments, the first housing 210 and the second housing 220 may have a symmetrical shape with respect to the first folding axis A1. The first housing 210 and the second housing 220 may have different angles or distances from each other depending on whether the multi-foldable electronic device 200 is in an open state, a closed state, or an intermediate state.

In an embodiment, the first housing 210 and the third housing 230 may be disposed on both sides (e.g., in the -x-axis direction and the x-axis direction) with respect to the second folding axis A2 in which the second hinge 202 is disposed, and may have a substantially symmetrical shape with respect to the second folding axis A2. According to various embodiments, the first housing 210 and the third housing 230 may have an asymmetrical shape with respect to the second folding axis A2. The first housing 210 and the third housing 230 may have different angles or distances from each other depending on whether the multi-foldable electronic device 200 is in an open state, a closed state, or an intermediate state.

According to various embodiments, an open state of the multi-foldable electronic device 200 may include the same meaning as an “open state” or an “unfolded state,” and a fully open state of the multi-foldable electronic device 200 may include the same meaning as a “fully open state” or a “fully unfolded state.” For example, a partially open state of the multi-foldable electronic device 200 may include the same meaning as an “intermediate state,” a “partially open state,” or a “partially unfolded state,” and a closed state of the multi-foldable electronic device 200 may include the same meaning as a “closed state” or a “folded state.

According to various embodiments, when the multi-foldable electronic device 200 is in the fully unfolded state, the first housing 210, the second housing 220, and the third housing 230 may form an angle of about 170° to about 185°. For example, when the multi-foldable electronic device 200 is in the partially unfolded state, an angle of about 10° to about 170° may be formed between the first housing 210, the second housing 220, and the third housing 230. For example, when the multi-foldable electronic device 200 is in the closed state, an angle of about 0° to about 10° may be formed between the first housing 210, the second housing 220, and the third housing 230. For example, the angles of the first housing 210, the second housing 220, and the third housing 230 in the fully unfolded state, the partially unfolded state, and the closed state are merely examples according to an embodiment, and are not limited thereto, and various other angles may be formed.

According to an embodiment, the width of the second hinge 202 in the horizontal direction (e.g., the -x-axis direction and the x-axis direction) may be configured to be greater than the width of the first hinge 201 in the horizontal direction (e.g., the -x-axis direction and the x-axis direction). For example, when the second housing 220 is first folded with respect to the first housing 210 and the third housing 230 is folded with respect to the first housing 210 such that the third housing 230 is disposed on the second housing 220, the width of the second hinge 202 may be configured to be wider than the width of the first hinge 201. For example, the first hinge 201 may be a first in-folding hinge, a narrow hinge, a slim hinge, or a small hinge having a narrower width in the horizontal direction than the second hinge 202. For example, the second hinge 202 may be a second in-folding hinge, a wide hinge, a broad hinge, or a big hinge having a greater width in the horizontal direction than the first hinge 201.

According to an embodiment, the second hinge 202 may have a larger curvature radius, operation radius, or rotation radius than the first hinge 201. The first hinge 201 may have a smaller curvature radius, operation radius, or rotation radius than the second hinge 202. In an embodiment, although it is described that the width in the horizontal direction of the second hinge 202 is configured to be greater than the width of the first hinge 201, the disclosure is not limited thereto, and the width in the horizontal direction of the first hinge 201 may be configured to be greater than the width of the second hinge 202 depending on a type and/or operation of the multi-foldable electronic device 200.

In an embodiment, a flexible display 240 may be disposed on the first housing 210, the first hinge 201, the second housing 220, the second hinge 202, and/or the third housing 230. For example, the flexible display 240 may be disposed across at least a portion of the front surface (e.g., in the z-axis direction) of the first housing 210, the first hinge 201, the second housing 220, the second hinge 202, and/or the third housing 230. The flexible display 240 may be a first display, a foldable display, or a main display.

In an embodiment, a sub-display 250 may be disposed on the rear surface (e.g., in the -z-axis direction) of the first housing 210. The sub-display 250 may be a second display or an auxiliary display. The flexible display 240 and/or the sub-display 250 may include the display module 160 illustrated in FIGS. 1A and 1B. The flexible display 240 and/or the sub-display 250 may include at least various embodiments related to the display module 160 illustrated in FIGS. 1A and 1B. The flexible display 240 and/or the sub-display 250 may perform substantially the same functions as the display module 160 illustrated in FIGS. 1A and 1B.

In the disclosure, a surface on which the flexible display 240 (e.g., the display module 160 of FIGS. 1A and 1B) is disposed may be defined as the front surface (e.g., in the z-axis direction) of the multi-foldable electronic device 200, and an opposite surface of the front surface may be defined as the rear surface (e.g., in the -z-axis direction) of the multi-foldable electronic device 200. A surface surrounding the space between the front surface (e.g., in the z-axis direction) and the rear surface (e.g., in the -z-axis direction) may be defined as the side surface of the multi-foldable electronic device 200.

In an embodiment, the flexible display 240 may include a first display area 240a disposed on the front surface (e.g., in the z-axis direction) of the first housing 210, the second display area 240b disposed on the front surface (e.g., in the z-axis direction) of the second housing 220, and a third display area 240c disposed on the front surface (e.g., in the z-axis direction) of the third housing 230. The first display area 240a, the second display area 240b, and the third display area 240c may be integrated to comprise the flexible display 240. According to various embodiments, when the multi-foldable electronic device 200 is in the unfolded state, the flexible display 240 may be configured to be disposed on most of the front surface of the multi-foldable electronic device 200 (e.g., in the z-axis direction). At least a portion of the flexible display 240 may be transformed into a flat or curved surface. The division of the flexible display 240 into the first display area 240a, the second display area 240b, and the third display area 240c may be an example division. The flexible display 240 may be fabricated as an overall seamless single screen. According to an embodiment, the sub-display 250 disposed on the rear surface (e.g., in the -z-axis direction) of the first housing 210 may include a fourth display area 250d.

According to an embodiment, when the multi-foldable electronic device 200 is in the open state, the first housing 210 may include a first surface 211 connected to at least a portion of the first hinge 201 and the second hinge 202 and disposed to face the front (e.g., in the z-axis direction) of the multi-foldable electronic device 200, a second surface 212 disposed to face away from the first surface 211, and/or a first side surface member 213 surrounding at least a portion of a first space between the first surface 211 and the second surface 212.

According to an embodiment, when the multi-foldable electronic device 200 is in the open state, the second housing 220 may include a third surface 221 connected to at least a portion of the first hinge 201 and disposed to face the front (e.g., in the z-axis direction) of the multi-foldable electronic device 200, a fourth surface 222 disposed to face away from the third surface 221, and/or a second side surface member 223 surrounding at least a portion of a second space between the third surface 221 and the fourth surface 222.

According to an embodiment, when the multi-foldable electronic device 200 is in the unfolded state, the third housing 230 may include a fifth surface 231 connected to at least a portion of the second hinge 202 and disposed to face the front (e.g., in the z-axis direction) of the multi-foldable electronic device 200, a sixth surface 232 disposed to face away from the fifth surface 231, and/or a third side surface member 233 surrounding at least a portion of the third space between the fifth surface 231 and the sixth surface 232.

According to various embodiments, when the multi-foldable electronic device 200 is in the unfolded state, the first surface 211, the third surface 221, and the fifth surface 231 may be oriented in substantially the same direction (e.g., the z-axis direction). When the multi-foldable electronic device 200 is in the unfolded state, the second surface 212, the fourth surface 222, and the sixth surface 232 may be oriented in substantially the same direction (e.g., the -z-axis direction).

According to various embodiments, when the first housing 210 and the second housing 220 of the multi-foldable electronic device 200 are in the folded state, the first surface 211 of the first housing 210 and the third surface 221 of the second housing 220 may be disposed to face each other. When the third housing 230 is in the folded state with respect to the first housing 210 of the multi-foldable electronic device 200, and the third housing 230 is disposed above (e.g., in the z-axis direction of) the second housing 220, the fourth surface 222 of the second housing 220 and the fifth surface 231 of the third housing 230 may be disposed to face each other.

According to various embodiments, the multi-foldable electronic device 200 may include a recess 245 formed to accommodate the flexible display 240 through structural coupling of the first housing 210, the second housing 220, and the third housing 230. The recess 245 may have substantially the same size as the flexible display 240.

According to various embodiments, when the multi-foldable electronic device 200 is in the fully unfolded state, the first housing 210, the second housing 220, and the third housing 230 may form an angle of about 170° to about 185°, and the first display area 240a of the flexible display 240, the second display area 240b, and the third display area 240c may form substantially the same plane.

According to various embodiments, the first housing 210 and the second housing 220 may form an angle that allows the first and second housings to be stopped at a predetermined folding angle between the folded state and the unfolded state using the first hinge 201 (e.g., free-stop function). In various embodiments, the second housing 220 may be rotated to move toward the second surface 212 (e.g., the rear surface) of the first housing 210 while being biased in an unfolding direction (e.g., the -z-axis direction) based on a predetermined inflection angle using the first hinge 201.

According to various embodiments, the first housing 210 and the third housing 230 may form an angle that allows the first and third housings to be stopped at a predetermined folding angle between the folded state and the unfolded state using the second hinge 202. In various embodiments, the third housing 230 may be rotated to move toward the second surface 212 (e.g., a rear surface) of the first housing 210 while being biased in the unfolding direction (e.g., the -z-axis direction) based on a predetermined inflection angle using the second hinge 202.

According to various embodiments, the flexible display 240 may be disposed to be supported by the first surface 211 of the first housing 210, the first hinge 201, the third surface 221 of the second housing 220, the second hinge 202, and the fifth surface 231 of the third housing 230. In an embodiment, the sub-display 250 (e.g., the fourth display area 250d) may be disposed such that the sub-display 250 is at least partially visible from outside through the second surface 212 in an inner space of the first housing 210. In various embodiments, the sub-display 250 may be disposed such that the sub-display 250 is visible from outside through the fourth surface 222 in an inner space of the second housing 220.

According to an embodiment, the flexible display 240 may be mainly used when the first housing 210, the second housing 220, and the third housing 230 of the multi-foldable electronic device 200 are in the partially unfolded state, and the sub-display 250 may be mainly used when the first housing 210, the second housing 220, and the third housing 230 of the multi-foldable electronic device 200 are in the folded state.

According to an embodiment, the multi-foldable electronic device 200 may include a first rear surface cover 270 disposed on the second surface 212 of the first housing 210, a second rear surface cover 280 disposed on the fourth surface 222 of the second housing 220, and/or a third rear surface cover 290 disposed on the sixth surface 232 of the third housing 230. In various embodiments, at least a portion of the first rear surface cover 270 may be integrally formed with a portion of the first side surface member 213. According to various embodiments, at least a portion of the second rear surface cover 280 may be integrated with a portion of the second side surface member 223. According to various embodiments, at least a portion of the third rear surface cover 290 may be integrated with a portion of the third side surface member 233. According to an embodiment, at least one of the first rear surface cover 270, the second rear surface cover 280, and the third rear surface cover 290 may be made of a substantially transparent plate (e.g., a glass plate including various coating layers, or a polymer plate) or an opaque plate.

According to various embodiments, the first rear surface cover 270 may be made of a substantially transparent plate of, for example, glass or polymer. The sub-display 250 (e.g., the fourth display area 250d) may be disposed to be visible from outside through the first rear surface cover 270 in the inner space of the first housing 210. According to various embodiments, the second rear surface cover 280 may be made of, for example, coated or colored glass, ceramic, polymer, metal (e.g., aluminum, stainless steel (STS), or magnesium), or an opaque plate such as a combination of two or more of these materials. According to various embodiments, the third rear surface cover 290 may be made of, for example, coated or colored glass, ceramic, polymer, metal (e.g., aluminum, stainless steel (STS), or magnesium), or an opaque plate such as a combination of two or more of these materials. For example, a camera module 271b (e.g., a second camera module) may be disposed in the third rear surface cover 290 disposed on the sixth surface 232 of the third housing 230.

According to various embodiments, the multi-foldable electronic device 200 may include at least one of an input module 261, sound output modules 263 and 265, sensor modules 267a, 267b, and 267c, camera modules 271a, 271b, and 271c, key input devices 273, an indicator (not illustrated), or a connector port 275. At least one of the above-described components may be omitted from the multi-foldable electronic device 200 or at least one other component may be additionally included.

According to an embodiment, the input module 261 may include at least one microphone disposed to detect the direction of sound. The input module 261 may include the input module 150 illustrated in FIG. 1A.

According to an embodiment, the sound output modules 263 and 265 may include at least one speaker. The sound output modules 263 and 265 may include a call receiver 263 disposed through the first side surface member 213 of the first housing 210, and at least one speaker 265 disposed on a portion of an upper portion (e.g., in the y-axis direction) and a portion of a lower portion (e.g., in the -y-axis direction) of the second side surface member 223 of the second housing 220, and/or on a portion of an upper portion (e.g., in the y-axis direction) and a portion of a lower portion (e.g., in the -y-axis direction) of the third side surface member 233 of the third housing 230. The sound output modules 263 and 265 may include the sound output module 155 illustrated in FIG. 1A.

According to an embodiment, the input module 261, the sound output modules 263 and 265, and the connector port 275 may be disposed in the inner space of the first housing 210, the second housing 220, and/or the third housing 230, and may be exposed to the external environment through one or more holes provided in the first housing 210, the second housing 220, and/or the third housing 230. In an embodiment, the holes provided in the first housing 210, the second housing 220, and/or the third housing 230 may be commonly used for the input module 261 and the sound output modules 263 and 265. In an embodiment, the sound output modules 263 and 265 may include a speaker (e.g., a piezo speaker) that operates without a hole formed in the first housing 210, the second housing 220 and/or the third housing 230.

According to various embodiments, the camera modules 271a, 271b, and 271c may include a first camera module 271a disposed on the first surface 211 of the first housing 210, a second camera module 271b disposed on the sixth surface 232 of the third housing 230, and/or a third camera module 271c disposed on the second surface 212 of the first housing 210.

According to an embodiment, the multi-foldable electronic device 200 may include a flash 295 disposed adjacent to the second camera module 271b. The flash 295 may include, for example, a light-emitting diode or a xenon lamp. According to an embodiment, the camera modules 271a, 271b, and 271c may include one or more lenses, an image sensor, and/or an image signal processor. In an embodiment, at least one of the camera modules 271a, 271b, and 271c may include two or more lenses (e.g., a wide-angle lens and a telephoto lens) and image sensors, and may be disposed together on one surface of the first housing 210, the second housing 220, and/or the third housing 230. For example, the camera modules 271a, 271b, and 271c may include the camera module 180 illustrated in FIG. 1A.

According to an embodiment, the sensor modules 267a, 267b, and 267c may generate electrical signals or data values corresponding to an internal operating state or an external environmental state of the multi-foldable electronic device 200. According to various embodiments, the sensor modules 267a, 267b, and 267c may include a first sensor module 267a disposed on the first surface 211 of the first housing 210, a second sensor module 267b disposed on the sixth surface 232 of the third housing 230, and/or a third sensor module 267c disposed on the second surface 212 of the first housing 210. For example, the sensor modules 267a, 267b, and 267c may include the sensor module 176 illustrated in FIG. 1A.

According to various embodiments, the multi-foldable electronic device 200 may further include an unillustrated sensor module, for example, at least one of a 6-axis sensor (e.g., an acceleration sensor and a gyro sensor), an angle sensor, a Hall sensor, an angular velocity sensor, a folding and unfolding detection sensor, a proximity sensor, a pressure sensor, a magnetic sensor, a biometric sensor, a temperature sensor, a humidity sensor, a gesture sensor, a grip sensor, a color sensor, an infrared (IR) sensor, an illuminance sensor, an ultrasonic sensor, an iris recognition sensor, a distance detection sensor (e.g., a time of flight (TOF) sensor or a light detection and ranging (LiDAR) sensor), and a fingerprint recognition sensor.

According to an embodiment, key input devices 273 may be disposed to be visually exposed outside through the third side surface member 233 of the third housing 230. In an embodiment, the key input devices 273 may also be disposed to be visually exposed to the outside through the second side surface member 223 of the second housing 220. In an embodiment, the multi-foldable electronic device 200 may not include some or all of the key input devices 273, and the key input devices 273 not included may be implemented in another form such as soft keys on the flexible display 240 and/or the sub-display 250. For example, the key input devices 273 may be implemented using touch sensors (e.g., the touch sensor 168a of FIG. 1B) and/or pressure sensors included in the flexible display 240 and/or the sub-display 250. In an embodiment, the key input devices 273 may include a power button and/or a volume control button of the multi-foldable electronic device 200.

According to an embodiment, the connector port 275 may include a connector (e.g., a USB connector or an interface connector port module (IF module)) for transmitting and/or receiving power and/or data with an external electronic device (e.g., the external electronic devices 102 and 104 of FIG. 1A). In an embodiment, the connector port 275 may be configured to perform a function for transmitting/receiving an audio signal to and from the external electronic device, or may further include a separate connector port (e.g., an ear jack hole) configured to perform an audio signal transmitting/receiving function. For example, the connector port 275 may be formed on a portion (e.g., in the -y-axis direction or in the lower portion) of the first side surface member 213 of the first housing 210. For example, the connector port 275 may include the connection terminal 178 illustrated in FIG. 1A.

According to various embodiments, one or more camera modules 271a and 271c among the camera modules 271a, 271b, and 271c, one or more sensor modules 267a and 267c among the sensor modules 267a, 267b, and 267c, and/or an indicator may be disposed to be visually exposed through at least one display (e.g., the flexible display 240 and/or the sub-display 250).

FIG. 2C is a diagram illustrating a side view of the multi-foldable electronic device in a state in which the first housing and the second housing are folded, and the first housing and the third housing are unfolded according to various embodiments. FIG. 2D is a diagram illustrating a side view of the multi-foldable electronic device in a state in which the first housing, the second housing, and the third housing are folded according to various embodiments.

According to an embodiment, FIG. 2C may be a view, as seen in the -y-axis direction, illustrating a state in which the second housing 220 of the multi-foldable electronic device 200 is folded toward the first housing 210 via the first hinge 201, and the first housing 210 and the third housing 230 are unfolded at about 180°. According to an embodiment, FIG. 2D may be a view, as seen in the -y-axis direction, illustrating a state in which the second housing 220 of the multi-foldable electronic device 200 is first folded toward the first housing 210 via the first hinge 201, and the folded first housing 210 and second housing 220 are subsequently folded toward the third housing 230 via the second hinge 202, such that the second housing 220 is disposed above (e.g., in the z-axis direction of) the third housing 230. For example, the multi-foldable electronic device 200 illustrated in FIGS. 2C and 2D may be a type folded in a predetermined form (e.g., an E-type).

According to various embodiments, the multi-foldable electronic device 200 may also be folded in various types of forms (e.g., a G-type or a Z-type). For example, like the G-type, the multi-foldable electronic device 200 may be folded such that the third housing 230 is first folded toward the first housing 210 via the second hinge 202, and the second housing 220 is subsequently folded toward the first housing 210 via the first hinge 201, such that the second housing 220 is disposed above (e.g., in the z-axis direction of) the third housing 230. For example, like the Z-type, the multi-foldable electronic device 200 may be folded such that the third housing 230 is folded toward the first housing 210 in an in-folding manner via the second hinge 202, and the second housing 220 is folded toward the second surface 212 of the first housing 210 in an out-folding manner via the first hinge 201.

Referring to FIGS. 2C and 2D, the multi-foldable electronic device 200 may include the first housing 210, the second housing 220, the third housing 230, a first hinge 201, and a second hinge 202.

According to an embodiment, the second housing 220 may be first folded above (e.g., in the z-axis direction of) the first housing 210 via the first hinge 201 (e.g., a first in-folding hinge). For example, after the second housing 220 is first folded onto the first housing 210 via the first hinge 201, the folded first housing 210 and second housing 220 may subsequently be folded toward the third housing 230 via the second hinge 202, such that the second housing 220 may be disposed above (e.g., in the z-axis direction of) the third housing 230. For example, when the second housing 220 is disposed above (e.g., in the z-axis direction of) the third housing 230, the fourth surface 222 of the second housing 220 and the fifth surface 231 of the third housing 230 may be disposed to face each other.

According to an embodiment, the first hinge 201 may have a first width. The second hinge 202 may have a second width. For example, the second width may be greater than the first width. For example, the second hinge 202 may have a larger curvature radius, operation radius, or rotation radius than the first hinge 201.

According to an embodiment, when the second housing 220 of the multi-foldable electronic device 200 is first folded toward the first housing 210 via the first hinge 201, and the folded first housing 210 and second housing 220 are subsequently folded toward the third housing 230 via the second hinge 202, such that the second housing 220 should be disposed above (e.g., in the z-axis direction of) the third housing 230, the second width of the second hinge 202 may be formed to have a larger curvature radius than the first width of the first hinge 201. For example, the first hinge 201 may be a first in-folding hinge, a narrow hinge, a slim hinge, or a small hinge having a smaller width in the horizontal direction (e.g., the x-axis direction and the -x-axis direction) than the second hinge 202. For example, the second hinge 202 may be a second in-folding hinge, a wide hinge, a broad hinge, or a big hinge having a greater width in the horizontal direction than the first hinge 201.

According to an embodiment, when the second housing 220 is first folded onto the first housing 210 via the first hinge 201 (e.g., a first in-folding hinge), and the folded first housing 210 and second housing 220 are subsequently folded toward the third housing 230 via the second hinge 202 (e.g., a second in-folding hinge), such that the second housing 220 is disposed above (e.g., in the z-axis direction of) the third housing 230, at least a portion of the sub-display 250 (e.g., the fourth display area 250d) disposed on the second surface 212 of the first housing 210 may be visible to the outside of the multi-foldable electronic device 200.

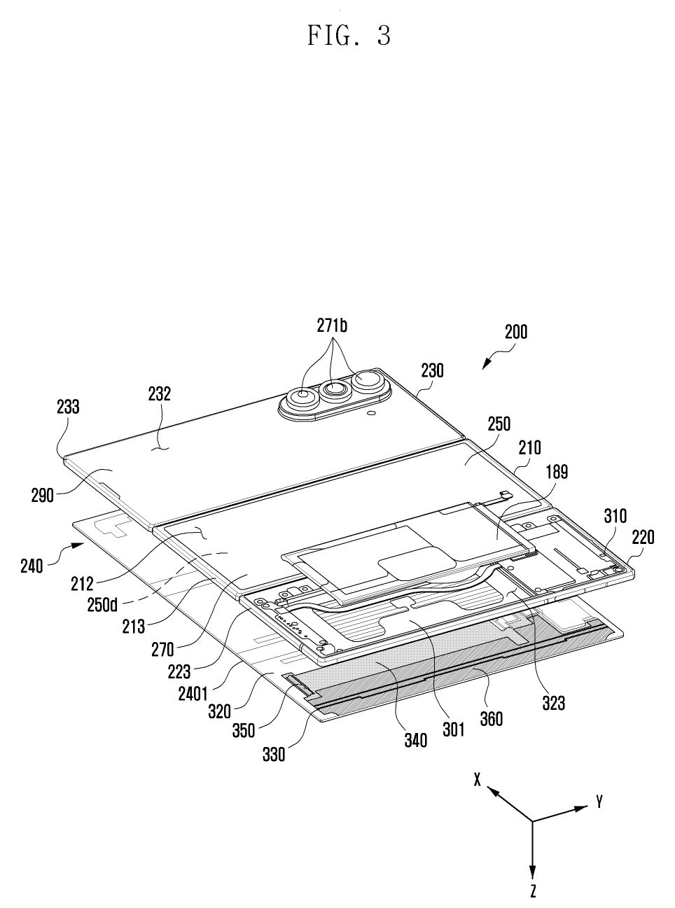

FIG. 3 is an exploded perspective view of a multi-foldable electronic device according to various embodiments.

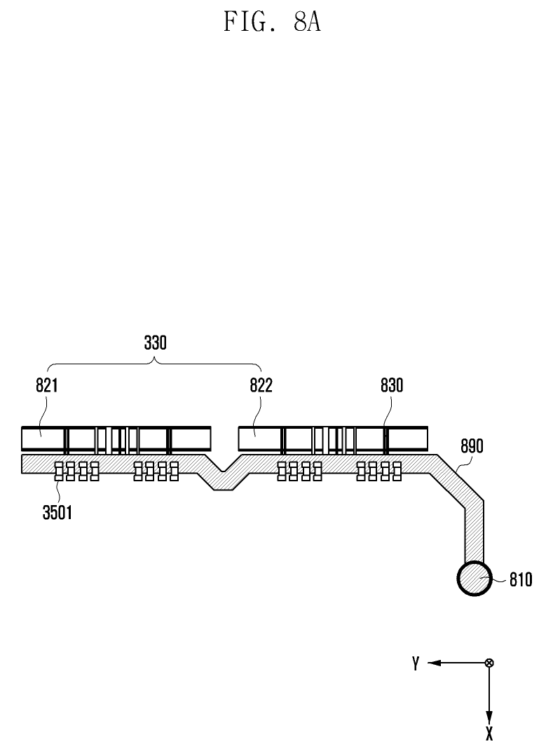

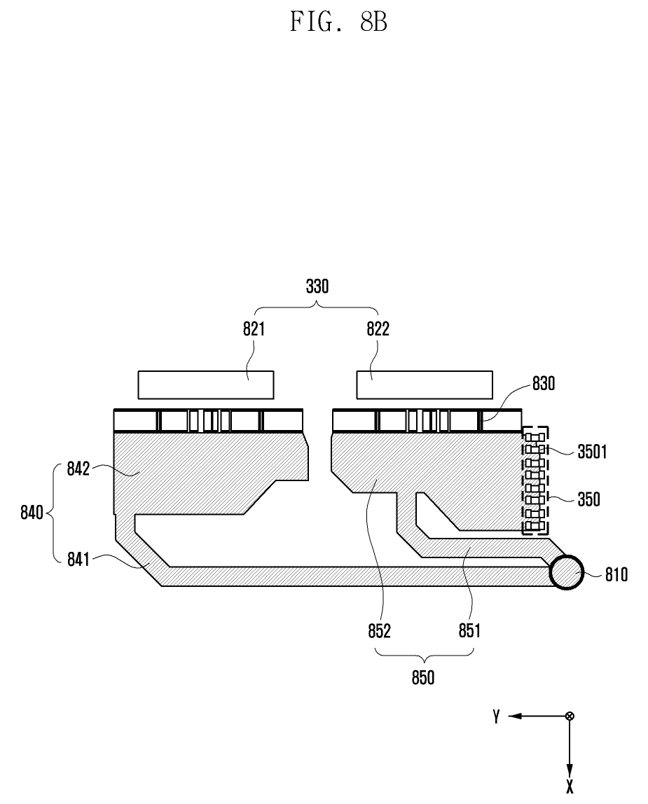

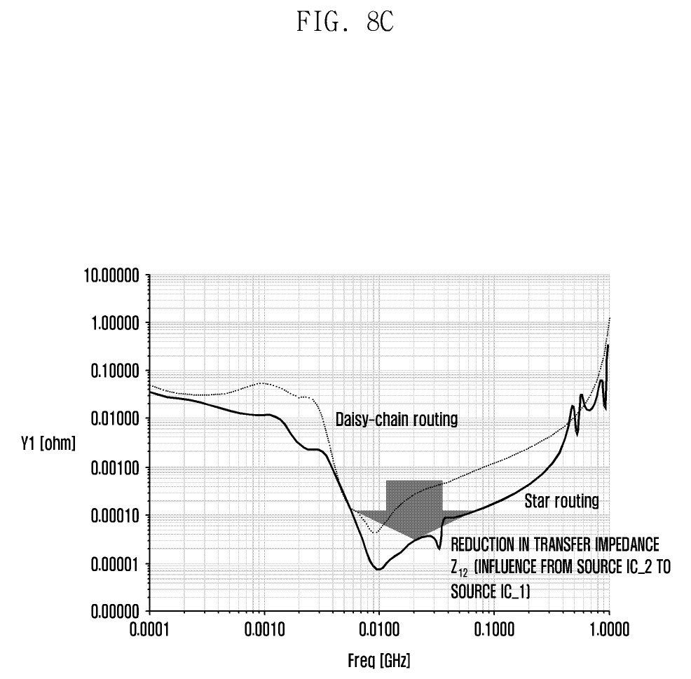

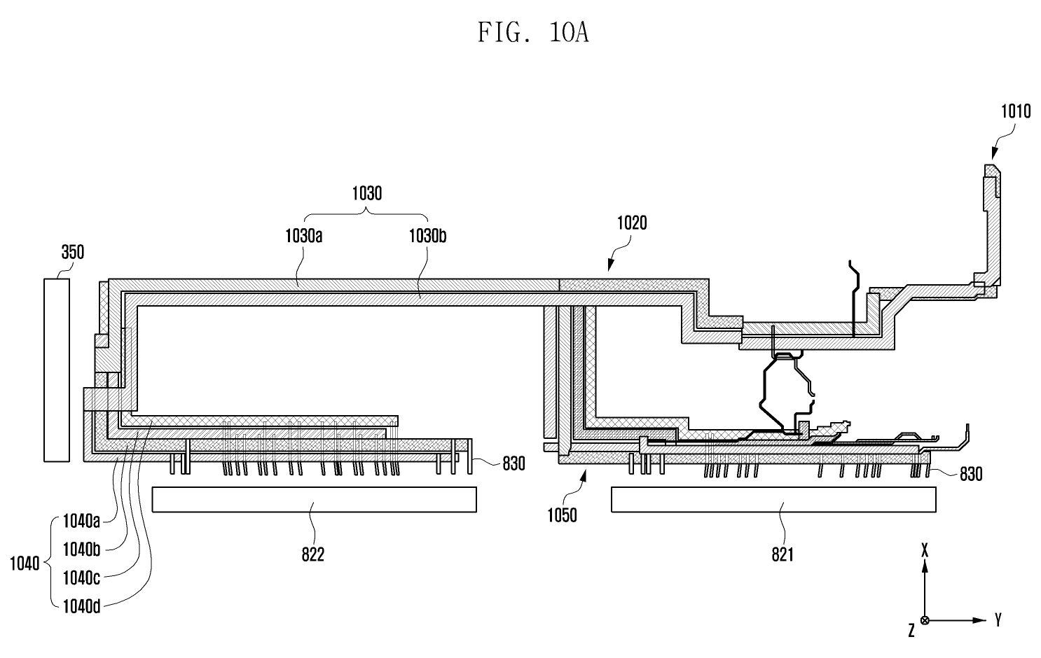

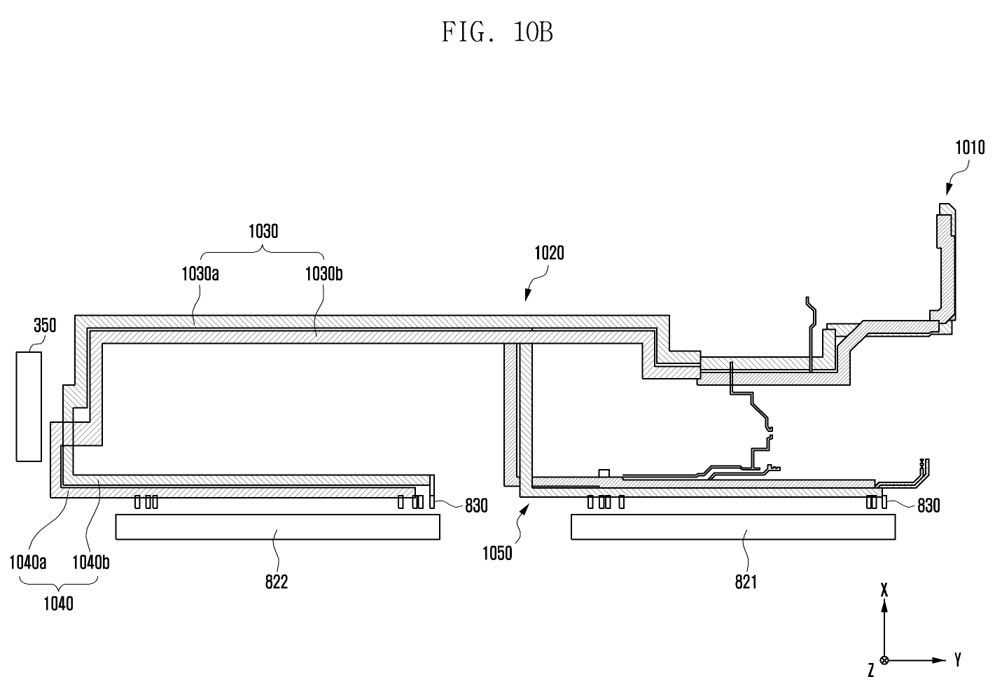

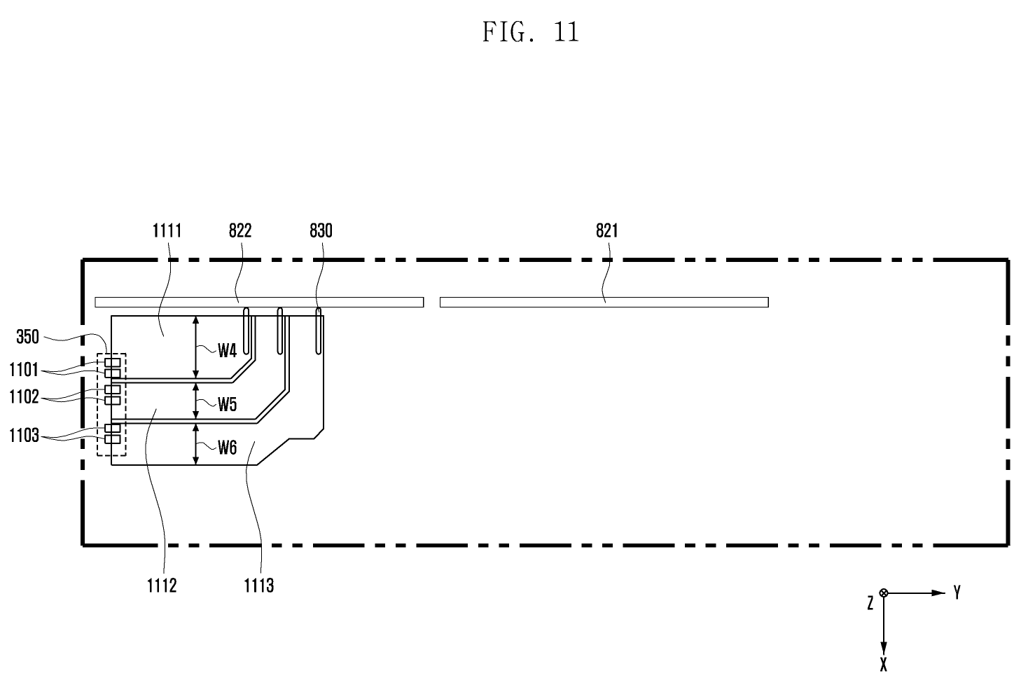

FIG. 3 may be an exploded perspective view in which power wires (e.g., the power wires 840 and 850 of FIG. 8B, the power wires 1030, 1040, and 1050 of FIG. 10B, and the power wires 1111 to 1113 of FIG. 11) configured to deliver power supplied through the printed circuit board 310 to the driver circuit 330, and the second rear surface cover 280 of the second housing 220 are not shown.

Referring to FIG. 3, the multi-foldable electronic device 200 may include a printed circuit board (PCB) 310, a substrate 320, a driver circuit 330, and/or a flexible printed circuit board (FPCB) 340.

In an embodiment, the printed circuit board 310 may be disposed to be accommodated in a housing (e.g., one of the first housing 210, the second housing 220, and the third housing 230 of FIGS. 2A to 2D). The printed circuit board 310 may be configured such that a processor (e.g., the processor 120 of FIG. 1A) is disposed thereon.

In an embodiment, the flexible display 240 may include a display panel 2401. In an embodiment, the display panel 2401 may be a flexible display panel or a foldable display panel. The display panel 2401 may be configured to be disposed on the substrate 320. The substrate 320 may be made of a flexible plastic material (e.g., polyimide (PI)). However, the disclosure is not limited thereto, and the substrate 320 may be made of various materials.

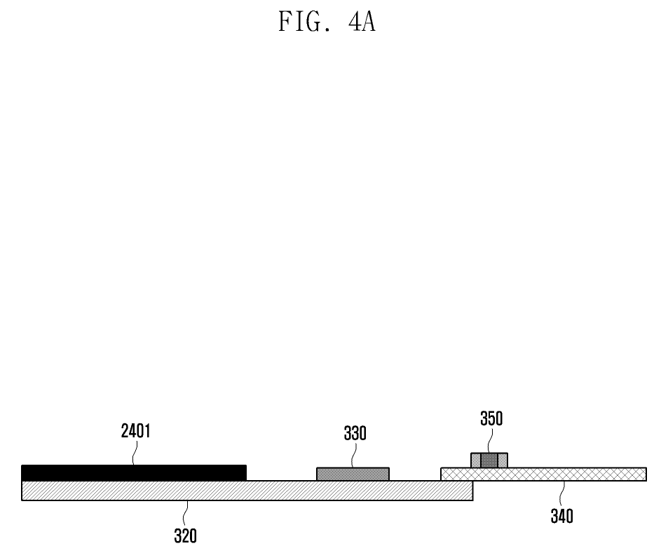

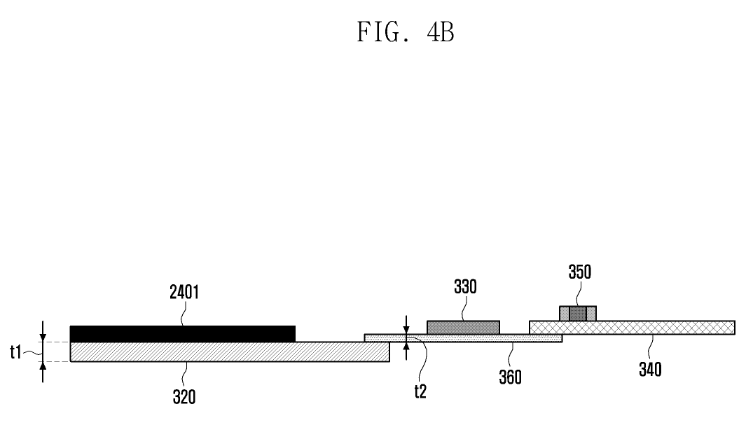

In an embodiment, the driver circuit 330 may be disposed under the display panel 2401 and configured to be electrically connected thereto. The driver circuit 330 may be a source driver integrated circuit (IC). The driver circuit 330 may be configured to adjust a voltage of data lines present in the display panel 2401 so as to adjust brightness of sub-pixels. In an embodiment, the driver circuit 330 may be disposed on the film substrate 360. However, the disclosure is not necessarily limited thereto, and as described below with reference to FIGS. 4A and 4B, the driver circuit 330 may be disposed not only on the film substrate 360 but also on the substrate 320.

In an embodiment, the film substrate 360 may be disposed to be connected to one end portion of the substrate 320. The film substrate 360 may be made of a plastic material having a property more flexible than the substrate 320 (e.g., PI or polyethylene naphthalate (PEN)). However, the disclosure is not necessarily limited thereto, and the film substrate 360 may be made of various materials.

In an embodiment, the flexible printed circuit board 340 may be configured to be electrically connected to the driver circuit 330. The flexible printed circuit board 340 may be electrically connected to the driver circuit 330 via a connection pad (e.g., the connection pad 830 of FIGS. 8B, 10A, and 10B) positioned between the driver circuit 330 and the array of capacitors. The flexible printed circuit board 340 may be disposed on the substrate 320. In an embodiment, the flexible printed circuit board 340 may include a power wire (e.g., the power wires 840 and 850 of FIG. 8B, the power wires 1030, 1040, and 1050 of FIG. 10B, and the power wires 1111 to 1113 of FIG. 11) configured to deliver power supplied via the printed circuit board 310 to the driver circuit 330, and an array of capacitors 350 electrically coupled to the power wires (e.g., the power wires 840 and 850 of FIG. 8B, the power wires 1030, 1040, and 1050 of FIG. 10B, and the power wires 1111 to 1113 of FIG. 11).

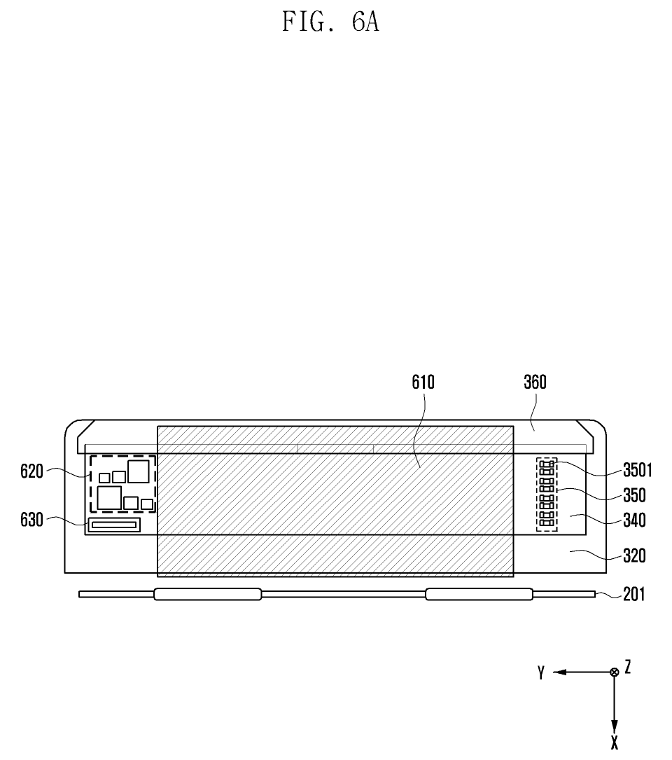

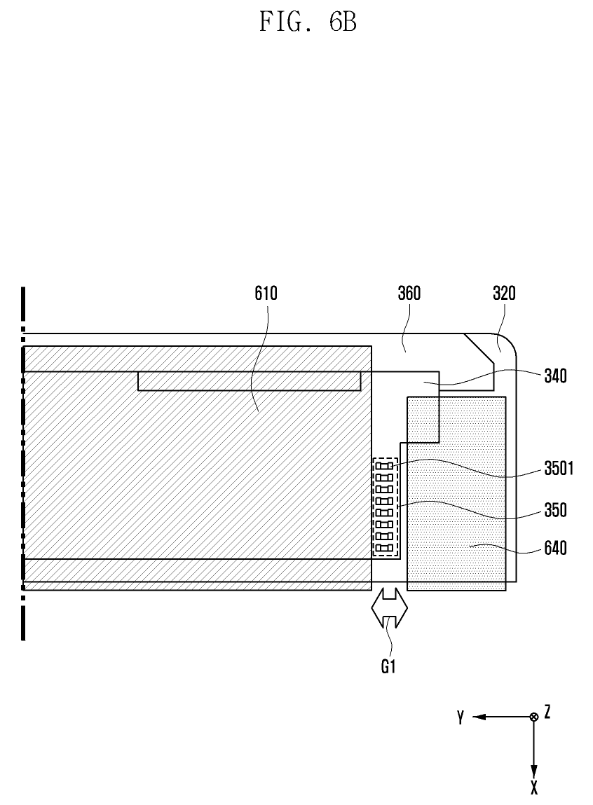

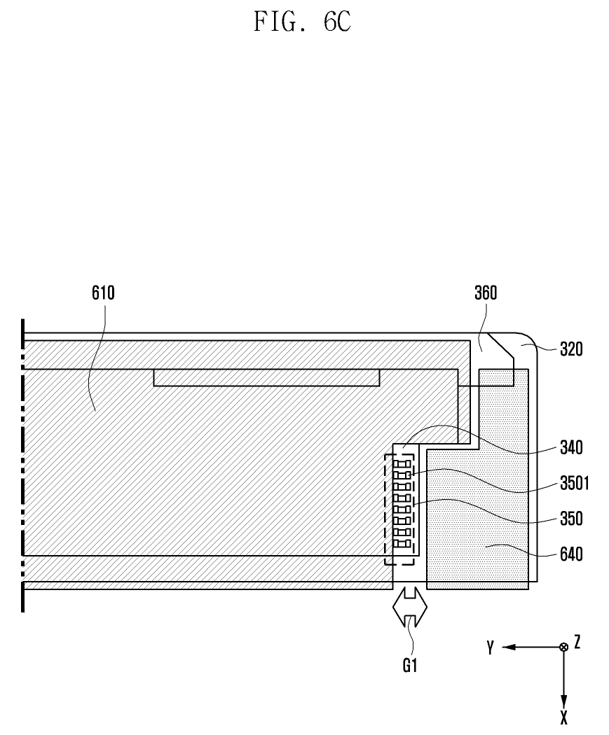

In an embodiment, the array of capacitors 350 may refer to an aggregate of multiple capacitors (e.g., the capacitors 3501 of FIGS. 6A and 6B). In an embodiment, the array of capacitors 350 may be configured to be arranged along a direction (e.g., the x-axis direction) substantially perpendicular to a longitudinal direction (e.g., the y-axis direction) of the driver circuit 330.

In an embodiment, the array of capacitors 350 may include multiple decoupling capacitors (e.g., the capacitors 3501 of FIGS. 6A and 6B). In an embodiment, the array of capacitors 350 may be configured to connect the power wires (e.g., the power wires 840 and 850 of FIG. 8B, the power wires 1030, 1040, and 1050 of FIG. 10B, and the power wires 1111 to 1113 of FIG. 11) and a ground (not illustrated). In an embodiment, the array of capacitors 350 may be configured to reduce noise delivered to the driver circuit 330 by absorbing high-frequency noise. In an embodiment, the array of capacitors 350 may be configured to maintain power stability by reducing fluctuations of a power voltage in response to instantaneous current changes. In addition, the array of capacitors 350 may be configured to reduce impedance of the power wires (e.g., the power wires 840 and 850 of FIG. 8B, the power wires 1030, 1040, and 1050 of FIG. 10B, and the power wires 1111 to 1113 of FIG. 11) in a high-frequency band so that a current supply may be smoothly performed.

In an embodiment, the battery 189 may be accommodated in a battery seating portion 323 formed in a bracket 301 of the second housing 220. Here, the bracket 301 may refer to an area in which an electronic component (e.g., the battery 189) may be disposed inside the second housing 220.

FIG. 4A is a diagram illustrating a state in which a driver circuit is disposed on a substrate according to various embodiments. FIG. 4B is a diagram illustrating a state in which a driver circuit is disposed on a film substrate according to various embodiments.

FIGS. 4A and 4B illustrate respective components arranged horizontally for convenience of understanding, and are not limited to the structures in which the components are actually disposed as illustrated.

Referring to FIG. 4A, in an embodiment, the driver circuit 330 may be disposed on the substrate 320. The flexible printed circuit board 340 may be configured to be electrically connected to the driver circuit 330 via one end portion of the substrate 320. Such a connection structure may be defined as a chip-on-plastic (COP) structure.

Referring to FIG. 4B, in an embodiment, the driver circuit 330 may be disposed on the film substrate 360. The flexible printed circuit board 340 may be configured to be electrically connected to the driver circuit 330 via one end portion of the film substrate 360. Such a connection structure may be defined as a chip-on-film (COF) structure. In an embodiment, a thickness t2 of the film substrate 360 may greater than a thickness t1 of the substrate 320.

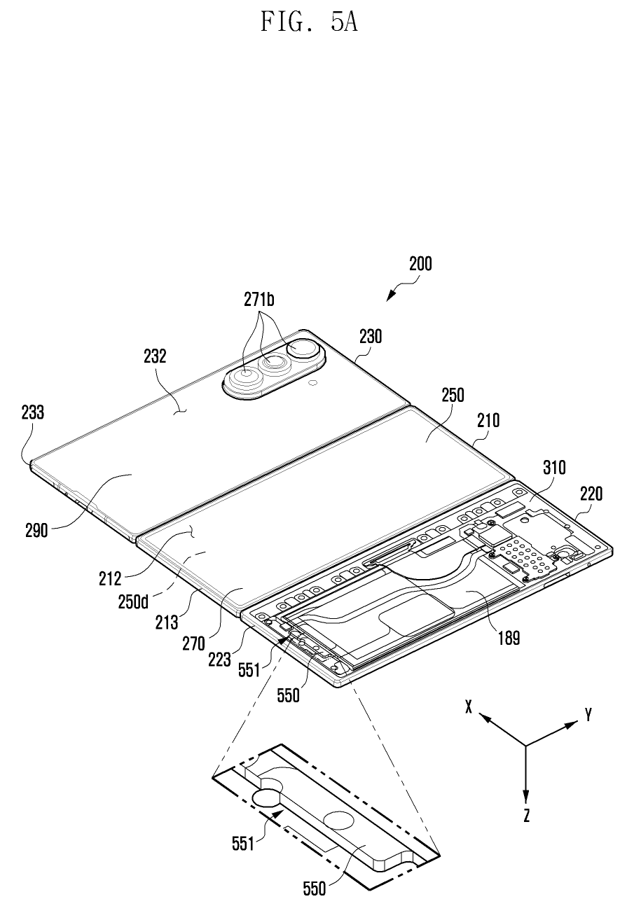

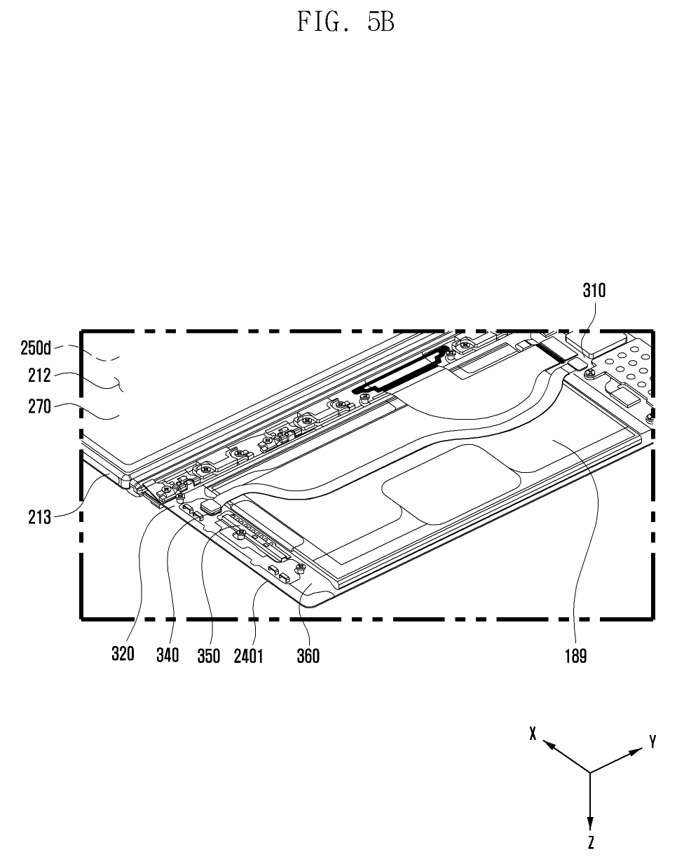

FIG. 5A is a perspective view illustrating a multi-foldable electronic device in an assembled state in which a second rear cover is removed according to various embodiments. FIG. 5B is a partially enlarged perspective view illustrating the multi-foldable electronic device in a state in which the second housing and a second rear cover are removed according to various embodiments.

FIG. 5B may be a view that illustrates a state in which only the second housing 220 is further removed from the multi-foldable electronic device 200 illustrated in FIG. 5A.

Referring to FIGS. 5A and 5B, in an embodiment, a bracket (e.g., the bracket 301 of FIG. 3) of the second housing 220 may include a recess 550 formed to correspond to a direction in which an array of capacitors 350 protrudes. The recess 550 may be configured to be recessed rearward (e.g., in the -Z-axis direction) from a seating surface of a battery seating portion (e.g., the battery seating portion 323 of FIG. 3) so as to secure a space in which the array of capacitors 350 is accommodated. The recess 550 may include a hole 551 formed such that at least a portion of the array of capacitors 350 is visible. In an embodiment, the bracket (e.g., the bracket 301 of FIG. 3) of the second housing 220 may include a hole formed over an entire area in which the recess (e.g., the recess 550 of FIG. 5A) is disposed, such that at least a portion of the array of capacitors 350 is visible.

In an embodiment, the array of capacitors 350 may be configured, as described above with reference to FIG. 3, to be arranged along a direction (e.g., the X-axis direction) substantially perpendicular to the longitudinal direction (e.g., the Y-axis direction) of the driver circuit (e.g., the driver circuit 330 of FIG. 3). In this manner, a battery 189 having increased capacity may be configured to be disposed in the multi-foldable electronic device 200. In an embodiment, the battery 189 may be disposed to overlap at least a portion of the flexible printed circuit board 340, at least a portion of the driver circuit 330, and/or at least a portion of the film substrate 360 when viewed from above the display panel 2401.

FIGS. 6A, 6B and 6C are diagrams illustrating plan views of an array of capacitors according to various embodiments.

Referring to FIGS. 6A and 6B, in an embodiment, the array of capacitors 350 may be configured to be arranged along a direction (e.g., the X-axis direction) substantially perpendicular to a longitudinal direction of the first hinge 201 (e.g., the Y-axis direction). In an embodiment, the array of capacitors 350 may be disposed in a first area positioned in a first direction (e.g., the -Y-axis direction) of a battery placement area 610. In an embodiment, the battery placement area 610 may be an area in which a battery (e.g., the battery 189 of FIGS. 3, 5A, and 5B) may be disposed.

In an embodiment, the capacitors 3501 of the array of capacitors 350 may each have a predetermined width (e.g., a length parallel to the Y-axis direction). Accordingly, by arranging the array of capacitors 350 along a direction substantially perpendicular to the longitudinal direction (e.g., the Y-axis direction) of the driver circuit (e.g., the driver circuit 330 of FIG. 3) and/or the longitudinal direction of the first hinge 201 (e.g., the Y-axis direction), an increase width of the battery placement area 610 may be greater than an increase width of the battery placement area 610 obtained by arranging the array of capacitors 350 in a direction parallel to the longitudinal direction of the driver circuit (e.g., the driver circuit 330) and/or the longitudinal direction of the first hinge 201. As the battery placement area 610 is expanded, the capacity of the battery may be increased while maintaining the thickness of the battery (e.g., a length in the Z-axis direction) slim.

In an embodiment, the flexible printed circuit board 340 may include a driver circuit placement area 620 and a connector 630 disposed in a second area positioned in a second direction (e.g., the +Y-axis direction) of the battery placement area 610, in which driver circuits other than the driver circuit 330 (e.g., the driver circuit 330 of FIG. 3) may be disposed.

In an embodiment, an electronic component including at least one speaker (e.g., the speaker 265 of FIGS. 2A, 2C and 2D) and/or a SIM card module (not illustrated) may be disposed on an electronic component placement area 640. In an embodiment, the array of capacitors 350 may be disposed between the battery disposed on the battery placement area 610 (e.g., the battery 189 of FIGS. 3, 5A, and 5B) and the electronic component disposed on the electronic component placement area 640. To secure an area in which the array of capacitors 350 may be disposed, the battery placement area 610 and the electronic component placement area 640 may be spaced apart by a predetermined separation distance G1.

Referring to FIG. 6C, the battery placement area 610 may have various areas, so as to allow irregular-type batteries (e.g., the battery 189 of FIGS. 3, 5A, and 5B) to be disposed thereon. In this manner, a battery with an increased capacity (e.g., the battery 189 of FIGS. 3, 5A, and 5B) may be configured to be disposed. Even in this case, the array of capacitors 350 may be disposed in an area spaced apart by the predetermined separation distance G1 between the battery placement area 610 and the electronic component placement area 640.

In an embodiment, the battery (e.g., the battery 189 of FIGS. 3, 5A, and 5B) may be disposed such that, when viewed from above the display panel (e.g., the display panel 2401 of FIG. 3), the battery does not substantially overlap the array of capacitors 350.

Although the electronic device 200 according to an embodiment of the disclosure illustratively illustrates a multi-foldable type electronic device, the disclosure is not necessarily limited thereto. The electronic device 200 may include a first housing and a second housing rotatably connected to each other, a display panel accommodated in the first housing and the second housing. The display panel may be configured to be folded or unfolded with respect to a folding axis according to folding or unfolding of the first housing and the second housing, and the array of capacitors 350 may be configured to be disposed substantially perpendicular to the folding axis.

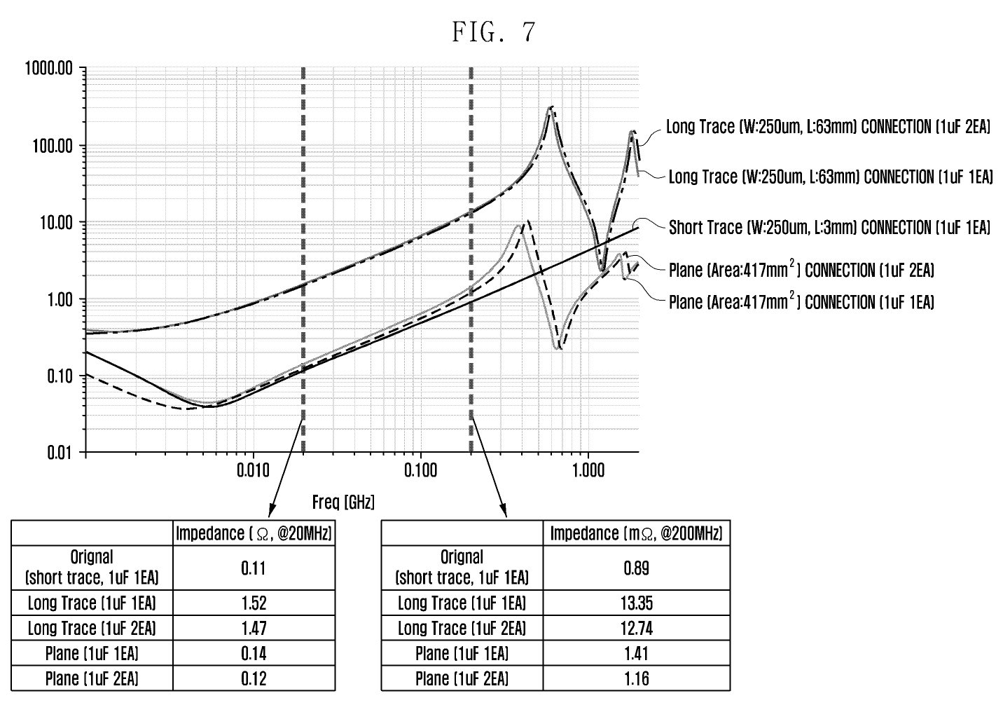

FIG. 7 is a graph illustrating impedance comparison results between embodiments of the disclosure and comparative examples.

Referring to FIG. 7, the “Plane Connection” may refer to an example including a power connection structure according to an embodiment of the disclosure. The “Plane Connection” may refer to a power connection structure in which an array of capacitors (e.g., the array of capacitors 350 of FIG. 3) is disposed along a direction substantially perpendicular to a longitudinal direction of a driver circuit (e.g., the driver circuit 330 of FIG. 3), and the array of capacitors (e.g., the array of capacitors 350 of FIG. 3) and the driver circuit (e.g., the driver circuit 330 of FIG. 3) are connected by a power plane connection (e.g., a plane connection). The power plane connection may refer to a power connection structure illustrated in FIG. 8B described below. Through such a power connection structure, parasitic resistance and parasitic inductance may be reduced.

The “Short Trace Connection (Original)” may refer to a comparative example in which a plurality of capacitors are disposed in a power connection structure along a longitudinal direction of a driver circuit (e.g., the driver circuit 330 of FIG. 3). The “Long Trace Connection” may refer to a comparative example in which an array of capacitors (e.g., the array of capacitors 350 of FIG. 3) is disposed along a direction substantially perpendicular to a longitudinal direction of a driver circuit (e.g., the driver circuit 330 of FIG. 3), and the array of capacitors (e.g., the array of capacitors 350 of FIG. 3) and the driver circuit (e.g., the driver circuit 330 of FIG. 3) are connected by a power line connection (e.g., a trace connection).

Referring to FIG. 7, in the comparative example of the “Short Trace Connection,” a plurality of capacitors may be disposed adjacent to the driver circuit (e.g., the driver circuit 330 of FIG. 3) along the longitudinal direction of the driver circuit (e.g., the driver circuit 330 of FIG. 3) so as to provide stable power supply. However, in the comparative example of the “Short Trace Connection,” due to the arrangement of the plurality of capacitors, there is a problem in that efficient placement of electronic components is difficult.

For efficient placement of electronic components, in the comparative example of the “Long Trace Connection,” an array of capacitors (e.g., the array of capacitors 350 of FIG. 3) may be disposed along a direction substantially perpendicular to the longitudinal direction of the driver circuit (e.g., the driver circuit 330 of FIG. 3), and when a power line connection is made, an impedance value may be increased by 10 times or more compared to the comparative example of the “Short Trace Connection.”

However, according to an embodiment of the disclosure, an array of capacitors (e.g., the array of capacitors 350 of FIG. 3) may be disposed along a direction substantially perpendicular to the longitudinal direction of a driver circuit (e.g., the driver circuit 330 of FIG. 3), and by connecting the array of capacitors (e.g., the array of capacitors 350 of FIG. 3) and the driver circuit (e.g., the driver circuit 330 of FIG. 3) via a power plane connection, the electronic device may be configured to obtain an impedance value at a level equivalent to that of the comparative example of the “Short Trace Connection.”

In an embodiment, power stability may be secured by connecting a power plane connection to more layers, thereby achieving a lower impedance value. The plane is not limited to a specific shape, but may be configured in various shapes including a trace having a great width, and the size of the plane and the number of connected layers may be varied depending on a separation distance between the array of capacitors (e.g., the array of capacitors 350 of FIG. 3) and the driver circuit (e.g., the driver circuit 330 of FIG. 3), and on a stacked structure of a flexible printed circuit board (e.g., the flexible printed circuit board 340 of FIG. 3).

FIG. 8A is a diagram illustrating a power wire configuration of a comparative example. FIG. 8B is a diagram illustrating a power wire configuration according to various embodiments. FIG. 8C is a graph illustrating impedance comparison results between the power wire configuration according to the disclosure and the power wire configuration of the comparative example.

Referring to FIG. 8A, the comparative example illustrates a configuration in which a first driver circuit 821 and a second driver circuit 822 of a plurality of driver circuits 330 share one power wire 890 from a voltage regulator module (VRM) (e.g., a voltage regulator) 810 and are electrically connected to capacitors 3501 via connection pads 830. The connection configuration of the comparative example illustrated in FIG. 8A may be referred to as a daisy-chain routing scheme. Such a power wiring configuration of the comparative embodiment may easily deliver voltage variations and noise generated by each of the plurality of driver circuits 330 to another driver circuit 330.

Referring to FIG. 8B, a first driver circuit 821 and a second driver circuit 822 of a plurality of driver circuits 330 may be configured to be connected to independent power wires 840 and 850 branched from the voltage regulator module 810 via connection pads 830. The power wires 840 and 850 may include longitudinal portions 841 and 851 and portions 842 and 852 having at least partially a polygonal plane shape. The connection configuration illustrated in FIG. 8B may be referred to as a star routing scheme.

Such a connection scheme may reduce the transmission of voltage variations and noise generated in each of the first driver circuit 821 and the second driver circuit 822 to another driver circuit. The amount of voltage noise delivered from another driver circuit may be represented by a transfer impedance value. The lower the transfer impedance value is, the smaller the effect of voltage variations caused by current consumption in another driver circuit may be.

Referring to FIG. 8C, the horizontal axis may represent frequency, and the vertical axis may represent transfer impedance. According to the power wire configuration (e.g., a star routing scheme) of the disclosure (see FIG. 8B), it may be identified that transfer impedance values are measured to be lower and voltage stability is increased compared to a case in which the power wire configuration (e.g., a daisy-chain routing scheme) of the comparative embodiment (see FIG. 8A) is applied.

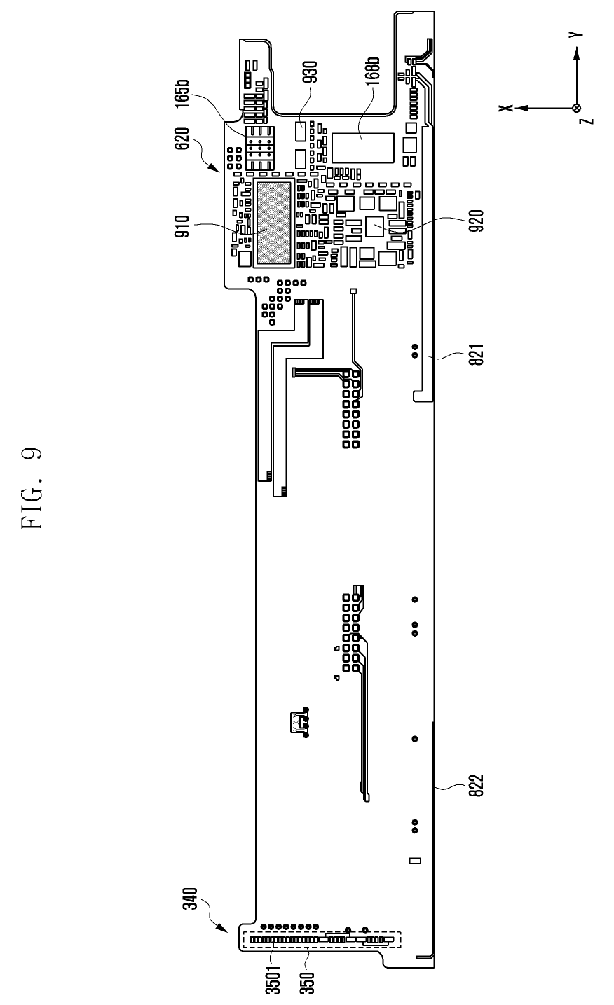

FIG. 9 is a diagram illustrating a plan view of a flexible printed circuit board according to various embodiments.

Referring to FIG. 9, an array of capacitors 350 may be disposed along a direction (e.g., the X-axis direction) perpendicular to a longitudinal direction (e.g., the Y-axis direction) of a first driver circuit 821 and a second driver circuit 822 on one side (e.g., in the -Y-axis direction) of the flexible printed circuit board 340.

In an embodiment, other driver circuits, other than the first driver circuit 821 and the second driver circuit 822, may be disposed in a first area 620 on the other side (e.g., in the Y-axis direction) of the flexible printed circuit board 340. Other driver circuits may include a timing controller integrated circuit (IC) 910, a power management integrated circuit (PMIC) 920, a level shifter integrated circuit 930, memory 165b, and/or a touch sensor IC 168b.

In an embodiment, the timing controller IC 910 may be configured to control signals and an amount of data required to drive the first driver circuit 821 and the second driver circuit 822 over time. The power management IC 920 may be configured to supply a voltage and a current for operating the first driver circuit 821 and the second driver circuit 822. The level shifter IC 930 may be configured to convert a voltage of a signal so as to deliver the signal between circuits using different voltage levels.

In an embodiment, a battery (e.g., the battery 189 of FIGS. 3, 5A, and 5B) may be disposed such that, when viewed from above the display panel (e.g., the display panel 2401 of FIG. 3), the battery does not substantially overlap the other driver circuits 910, 920, 930, 165b, and 168b.

FIGS. 10A and 10B are diagrams illustrating example power wires according to various embodiments. FIG. 11 is a diagram illustrating a plurality of power wire connection structures in a driver circuit according to various embodiments.

FIG. 10B may illustrate a state in which a third capacitor wire portion 1040c and a fourth capacitor wire portion 1040d of a second power wire portion 1040 and a portion of a third power wire portion 1050 among the power wire configurations of FIG. 10A are not shown for ease of understanding.

Referring to FIGS. 10A and 10B, in an embodiment, the power wires may include a first power wire portion 1030, a second power wire portion 1040, and a third power wire portion 1050 independently branched from a voltage regulator 1010 at a branch point 1020.

In an embodiment, the first power wire portion 1030 may be configured such that at least one capacitor (e.g., the capacitor 3501 of FIG. 9) included in the array of capacitors 350 is electrically connected to the voltage regulator 1010 connected to a printed circuit board (e.g., the printed circuit board 310 of FIG. 3). The first power wire portion 1030 may include a first voltage connection wire portion 1030a and a second voltage connection wire portion 1030b. However, the disclosure is not limited thereto, and the number of voltage connection wire portions may be variously configured.

In an embodiment, the second power wire portion 1040 may be configured such that at least one capacitor (e.g., the capacitor 3501 of FIG. 9) is electrically connected to a connection pad 830 on the side of a second driver circuit 822. In an embodiment, the width of the second power wire portion 1040 may be greater than the width of the connection pad 830.

Referring to FIG. 11, a plurality of capacitors (e.g., the capacitor 3501 of FIG. 9) forming the array of capacitors 350 may be defined as a first capacitor 1101, a second capacitor 1102, and a third capacitor 1103, in order of proximity to the second driver circuit 822. That is, the second capacitor 1102 may be configured to be disposed farther from the second driver circuit 822 than the first capacitor 1101.

In an embodiment, the second power wire portion (e.g., the second power wire portion 1040 of FIGS. 10A and 10B) may include a first capacitor wire portion 1111 corresponding to the first capacitor 1101, a second capacitor wire portion 1112 spaced apart from the first capacitor wire portion 1111 and corresponding to the second capacitor 1102, and a third capacitor wire portion 1113 spaced apart from the second capacitor wire portion 1112 and corresponding to the third capacitor 1103. However, the disclosure is not necessarily limited thereto, and as illustrated in FIGS. 10A and 10B, the number of capacitor wire portions may be variously configured, such as including first to fourth capacitor wire portions 1040a to 1040d.

In an embodiment, the first capacitor wire portion (e.g., the first capacitor wire portion 1040a of FIGS. 10A and 10B and the first capacitor wire portion 1111 of FIG. 11) may include a first longitudinal portion extending substantially parallel to the longitudinal direction of the second driver circuit 822. The second capacitor wire portion (e.g., the second capacitor wire portion 1040b of FIGS. 10A and 10B and the second capacitor wire portion 1112 of FIG. 11) may include a second longitudinal portion extending substantially parallel to the longitudinal direction of the second driver circuit 822. In an embodiment, the first longitudinal portion may be configured to be disposed closer to the second driver circuit 822 than the second longitudinal portion.

Referring to FIG. 11, in an embodiment, a width w4 of a first portion of the first capacitor wire portion 1111 may be configured to be greater than a width w5 of the second capacitor wire portion 1112. Referring to FIG. 11, although a width w6 of the third capacitor wire portion 1113 is illustrated to be greater than the width w5 of the second capacitor wire portion 1112, the disclosure is not necessarily limited thereto, and the width w6 of the third capacitor wire portion 1113 may be configured to be smaller than or equal to the width w5 of the second capacitor wire portion 1112.

In an embodiment, the third power wire portion 1050 may be independently branched from the voltage regulator 1010 at a branch point 1020 and may be configured to be electrically connected to a connection pad 830 on the side of the first driver circuit 821.

In an embodiment, the second power wire portion 1040 and/or the third power wire portion 1050 may be configured, as illustrated in FIG. 8B, to have at least partially a polygonal plane shape when viewed from above the display panel (e.g., the display panel 2401 of FIG. 3).

According to various example embodiments of the disclosure, an electronic device (e.g., the electronic device 200 of FIG. 2A) may include a housing (e.g., the first housing 210, the second housing 220, and the third housing 230 of FIG. 2A), a printed circuit board (PCB) (e.g., the printed circuit board 310 of FIG. 3) accommodated in the housing 210, 220, 230 and having a processor (e.g., the processor 120 of FIG. 1A) disposed thereon, a substrate 320, a display panel (e.g., the display panel 2401 of FIG. 3) disposed on the substrate 320, a driver circuit (e.g., the driver circuit 330 of FIG. 3) disposed under the display panel 2401 and electrically connected to the display panel 2401, and a flexible printed circuit board (FPCB) (e.g., the flexible printed circuit board 340 of FIG. 3) electrically connected to the driver circuit 330. The flexible printed circuit board 340 may include a power wire (e.g., the power wires 1030 and 1040 of FIGS. 10A and 10B) configured to deliver power supplied via the printed circuit board 310 to the driver circuit 330, and an array of capacitors (e.g., the array of capacitors 350 of FIG. 3) electrically coupled to the power wires 1030 and 1040 and arranged at least partially substantially perpendicular to a longitudinal direction of the driver circuit 330 (821 and/or 822).

According to example embodiments of the disclosure, by arranging the array of capacitors 350 along a direction perpendicular to the longitudinal direction of the driver circuit 330 (821 and/or 822), the electronic device 200 may provide an increased area in which another component (e.g., the battery 189) may be disposed.

In addition, according to example embodiments of the disclosure, the electronic device 200 may be configured to stably deliver power to the driver circuit 330 (821 and/or 822).

In an example embodiment, the substrate 320 may be made of a flexible plastic material (e.g., PI), the driver circuit 330 may be disposed on the substrate 320, and the flexible printed circuit board 340 may be electrically connected to the driver circuit 330 via an end portion of the substrate 320.

In an example embodiment, the electronic device may further include a film substrate 360 connected to the end portion of the substrate 320. The film substrate 360 has a thickness smaller than that of the substrate 320 and is made of a more flexible plastic material (e.g., PI or PEN). The driver circuit 330 may be disposed on the film substrate 360, and the flexible printed circuit board 340 may be electrically connected to the driver circuit 330 via an end portion of the film substrate 360.

In an example embodiment, the flexible printed circuit board 340 may be electrically connected to the driver circuit 822 via a connection pad 830 positioned between the driver circuit 330 and the array of capacitors 350, and the power wire may include a first power wire portion 1030 configured to electrically connect at least one capacitor 3501 included in the array of capacitors 350 to a voltage regulator 810 connected to the printed circuit board 310, and a second power wire portion 1040 configured to electrically connect the at least one capacitor 3501 to the connection pad 830. The second power wire portion 1040 may have a width greater than that of the connection pad 830.

In an example embodiment, the second power wire portion 1040 may be configured to at least partially have a shape of a polygonal plane when viewed from above the display panel 2401.

In an example embodiment, the array of capacitors 350 may include a first capacitor 1101 and a second capacitor 1102 positioned farther from the driver circuit 822 than the first capacitor 1101, and the second power wire portion 1040 may include a first capacitor wire portion 1111 corresponding to the first capacitor 1101, and a second capacitor wire portion 1112 spaced apart from the first capacitor wire portion 1111 and corresponding to the second capacitor 1102.

In an example embodiment, the first capacitor wire portion 1040a may include a first longitudinal portion extending substantially parallel to the longitudinal direction of the driver circuit 822, the second capacitor wire portion 1040b may include a second longitudinal portion extending substantially parallel to the longitudinal direction of the driver circuit 822, and the first longitudinal portion may be disposed closer to the driver circuit 822 than the second longitudinal portion.

In an example embodiment, a first portion of the first capacitor wire portion 1111 may have a width w4 greater than a width w5 of a second portion of the second capacitor wire portion 1112 corresponding to the first portion.

In an example embodiment, the electronic device may further include a battery 189 disposed so as not to substantially overlap the array of capacitors 350 when viewed from above the display panel 2401.

In an example embodiment, the electronic device 200 may further include an electronic component disposed at one side of the electronic device 200, and when viewed from above the display panel 2401, the array of capacitors 350 may be configured to be disposed between the battery 189 and the electronic component.

In an example embodiment, the housing 210, 220, 230 may include a bracket 301, first and second surfaces of the bracket 301 opposite to each other may respectively support the display panel 2401 and the battery 189, and the first surface of the bracket 301 may include a recess 550 formed thereon so as to accommodate the array of capacitors 350.

In an example embodiment, the battery 189 may be disposed so as to at least partially overlap the driver circuit 330 when viewed from above the display panel 2401.

In an example embodiment, the electronic device may further include another driver circuit 910, 920, 930, and/or 168b disposed on the flexible printed circuit board 340, and when viewed from above the display panel 2401, the battery 189 may be configured to be disposed so as not to substantially overlap the other driver circuit 910, 920, 930, and/or 168b.

In an example embodiment, the driver circuit 330 may include a source IC, and the other driver circuit 910, 920, 930, and/or 168b may include at least one of a timing controller 910, a level shifter 930, a touch IC 168b, and a power management IC 920.

In an example embodiment, the flexible printed circuit board 340 may include a connector 630 connected to the printed circuit board 310, and when viewed from above the display panel 2401, each of the connector 630 and the other driver circuit 910, 920, 930, and/or 168b may be disposed in a first area positioned in a first direction of the flexible printed circuit board 340 with respect to the battery 189, and the array of capacitors 350 may be disposed in a second area positioned in a second direction opposite to the first direction of the flexible printed circuit board 340 with respect to the battery 189.

In an example embodiment, the housing may include a first housing and a second housing rotatably connected to each other, the display panel 2401 may form a foldable display panel 2401 accommodated in the first housing and the second housing and configured to be folded or unfolded with respect to a folding axis according to folding or unfolding of the housing, and the array of capacitors 350 may be arranged substantially perpendicular to the folding axis.

In an example embodiment, each of the printed circuit board 310 and the flexible printed circuit board 340 may be disposed in the first housing.

In an example embodiment, the housing 210, 220, 230 may include a first housing 210, a second housing 220, a third housing 230, a first hinge housing 201 disposed substantially between the first housing 210 and the second housing 220, and a second hinge housing 202 disposed substantially between the first housing 210 and the third housing 230. The housing may further include a first hinge assembly at least partially accommodated in the first hinge housing 201 and rotatably connected to the first housing 210 and the second housing 220, and a second hinge assembly at least partially accommodated in the second hinge housing 202 and rotatably connected to the first housing 210 and the third housing 230. The array of capacitors 350 may be configured to be arranged substantially perpendicular to a longitudinal direction of the first hinge assembly and a longitudinal direction of the second hinge assembly.

In an example embodiment, each of the printed circuit board 310 and the flexible printed circuit board 340 may be configured to be disposed in the second housing 220.

In an example embodiment, the electronic device may further include another flexible printed circuit board extending across the first housing 210, the second housing 220, the third housing 230, the first hinge housing 201, and the second hinge housing 202. The flexible printed circuit board 340 may be disposed in the first housing 210, the printed circuit board 310 may be disposed in the third housing 230, and the flexible printed circuit board 340 may be configured to be electrically connected to the printed circuit board 310 via the other flexible printed circuit board.

The electronic device according to various embodiments set forth herein may be one of various types of electronic devices. The electronic device may include, for example, a portable communication device (e.g., a smart phone), a computer device, a portable multimedia device, a portable medical device, a camera, a wearable device, a home appliance, or the like. The electronic device according to embodiments of the disclosure is not limited to those described above.

It should be appreciated that various example embodiments and the terms used therein are not intended to limit the technological features set forth herein to particular embodiments and the disclosure includes various changes, equivalents, or alternatives for a corresponding embodiment. With regard to the description of the drawings, similar reference numerals may be used to designate similar or relevant elements. A singular form of a noun corresponding to an item may include one or more of the items, unless the relevant context clearly indicates otherwise. As used herein, each of such phrases as "A or B," "at least one of A and B," “at least one of A or B,” "A, B, or C," "at least one of A, B, and C," and “at least one of A, B, or C,” may include any one or all possible combinations of the items enumerated together in a corresponding one of the phrases. Such terms as "a first," "a second," “the first,” and "the second" may be used to simply distinguish a corresponding element from another, and does not limit the elements in other aspect (e.g., importance or order). If an element (e.g., a first element) is referred to, with or without the term “operatively” or “communicatively”, as “coupled with/to” or “connected with/to” another element (e.g., a second element), the element may be coupled/connected with/to the other element directly (e.g., wiredly), wirelessly, or via a third element.

As used in various embodiments of the disclosure, the term "module" may include a unit implemented in hardware, software, or firmware, or any combination thereof, and may be interchangeably used with other terms, for example, "logic," "logic block," "component," or "circuit". The “module” may be a single integrated component, or a minimum unit or part thereof, adapted to perform one or more functions. For example, according to an embodiment, the “module” may be implemented in the form of an application-specific integrated circuit (ASIC).

According to various embodiments, each element (e.g., a module or a program) of the above-described elements may include a single entity or multiple entities, and some of the multiple entities may be separately disposed in another element. According to various embodiments, one or more of the above-described elements or operations may be omitted, or one or more other elements or operations may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

The various example embodiments of the disclosure illustrated and described herein are merely examples that have been presented to easily explain the technical contents of the disclosure and to aid in understanding of the disclosure, and are not intended to limit the scope of the disclosure. Therefore, the scope of the disclosure should be understood to include, in addition to the examples set forth herein, all changes and modifications derived based on the technical idea of the disclosure. It will also be understood than any of the embodiment(s) described herein may be used in connection with any other embodiment(s) described herein.

What is claimed is:

1. An electronic device comprising:
a housing;
a printed circuit board (PCB) accommodated in the housing and having a processor disposed thereon;
a substrate;
a display panel disposed on the substrate;
a driver circuit disposed under the display panel and electrically connected to the display panel; and
a flexible printed circuit board (FPCB) electrically connected to the driver circuit,
wherein the flexible printed circuit board comprises:
a power wire configured to deliver power supplied via the printed circuit board to the driver circuit; and
an array of capacitors electrically coupled to the power wire and arranged at least partially substantially perpendicular to a longitudinal direction of the driver circuit.

2. The electronic device of claim 1, wherein the substrate comprises a flexible plastic material,
wherein the driver circuit is disposed on the substrate, and
wherein the flexible printed circuit board is electrically connected to the driver circuit via an end portion of the substrate.

3. The electronic device of claim 1, further comprising:
a film substrate connected to an end portion of the substrate, the film substrate having a thickness less than a thickness of the substrate and comprising flexible plastic material having a flexibility greater than a flexibility of the substrate,
wherein the driver circuit is disposed on the film substrate, and
wherein the flexible printed circuit board is electrically connected to the driver circuit via the end portion of the film substrate.

4. The electronic device of claim 1, wherein the flexible printed circuit board is electrically connected to the driver circuit via a connection pad positioned between the driver circuit and the array of capacitors, and
wherein the power wire comprises:
a first power wire portion configured to electrically connect at least one capacitor included in the array of capacitors to a voltage regulator connected to the printed circuit board; and
a second power wire portion configured to electrically connect the at least one capacitor to the connection pad, the second power wire portion having a width greater than a width of the connection pad.

5. The electronic device of claim 4, wherein the second power wire portion at least partially has a shape of a polygonal plane when viewed from above the display panel.

6. The electronic device of claim 4, wherein the array of capacitors comprises a first capacitor and a second capacitor positioned farther from the driver circuit than the first capacitor, and
wherein the second power wire portion comprises a first capacitor wire portion corresponding to the first capacitor, and a second capacitor wire portion spaced apart from the first capacitor wire portion and corresponding to the second capacitor.

7. The electronic device of claim 6, wherein the first capacitor wire portion comprises a first longitudinal portion extending substantially parallel to a longitudinal direction of the driver circuit,
wherein the second capacitor wire portion comprises a second longitudinal portion extending substantially parallel to a longitudinal direction of the driver circuit, and
wherein the first longitudinal portion is disposed closer to the driver circuit than the second longitudinal portion.

8. The electronic device of claim 6, wherein a first portion of the first capacitor wire portion has a width greater than a width of a second portion of the second capacitor wire portion corresponding to the first portion.

9. The electronic device of claim 1, further comprising:
a battery disposed so as not to substantially overlap the array of capacitors when viewed from above the display panel.

10. The electronic device of claim 9, further comprising:
an electronic component disposed at one side of the electronic device,
wherein, when viewed from above the display panel, the array of capacitors is disposed between the battery and the electronic component.

11. The electronic device of claim 9, wherein the housing comprises a bracket,
wherein first and second surfaces of the bracket, which are opposite to each other, are configured to respectively support the display panel and the battery, and
wherein the first surface of the bracket comprises a recess formed thereon to accommodate the array of capacitors.

12. The electronic device of claim 9, wherein the battery is disposed to at least partially overlap the driver circuit when viewed from above the display panel.

13. The electronic device of claim 9, further comprising:
another driver circuit disposed on the flexible printed circuit board ,
wherein, when viewed from above the display panel, the battery is disposed to not substantially overlap the another driver circuit.

14. The electronic device of claim 13, wherein the driver circuit comprises a source integrated circuit (IC), and
wherein the another driver circuit comprises at least one of a timing controller, a level shifter, a touch IC, and a power management IC.

15. The electronic device of claim 13, wherein the flexible printed circuit board comprises a connector connected to the printed circuit board,
wherein, when viewed from above the display panel, each of the connector and the another driver circuit is disposed in a first area positioned in a first direction of the flexible printed circuit board with respect to the battery, and
wherein the array of capacitors is disposed in a second area positioned in a second direction opposite to the first direction of the flexible printed circuit board with respect to the battery.

16. The electronic device of claim 1, wherein the housing comprises a first housing and a second housing rotatably connected to each other,
wherein the display panel comprises a foldable display panel accommodated in the first housing and the second housing and configured to be folded or unfolded with respect to a folding axis according to folding or unfolding of the housing, and
wherein the array of capacitors is arranged substantially perpendicular to the folding axis.

17. The electronic device of claim 16, wherein each of the printed circuit board and the flexible printed circuit board is disposed in the first housing.

18. The electronic device of claim 1, wherein the housing comprises a first housing, a second housing, a third housing, a first hinge housing disposed substantially between the first housing and the second housing, and a second hinge housing disposed substantially between the first housing and the third housing,
wherein the housing further comprises:
a first hinge assembly comprising a hinge at least partially accommodated in the first hinge housing and rotatably connected to the first housing and the second housing; and
a second hinge assembly comprising a hinge at least partially accommodated in the second hinge housing and rotatably connected to the first housing and the third housing, and
wherein the array of capacitors is arranged substantially perpendicular to a longitudinal direction of the first hinge assembly and a longitudinal direction of the second hinge assembly.

19. The electronic device of claim 18, wherein each of the printed circuit board and the flexible printed circuit board is disposed in the second housing.

20. The electronic device of claim 18, further comprising:
another flexible printed circuit board extending across the first housing, the second housing, the third housing, the first hinge housing, and the second hinge housing,
wherein the flexible printed circuit board is disposed in the first housing,
wherein the printed circuit board is disposed in the third housing, and
wherein the flexible printed circuit board is electrically connected to the printed circuit board through the other flexible printed circuit board.
